(19) United States
(12) Patent Application Publication
(10) Pub. No.: US 2023/0137820 A1
(43) Pub. Date: May 4, 2023

(54) PHOSPHORESCENT aNHC-BASED PLATINUM (II) COMPLEXES

(71) Applicant: TECHNISCHE UNIVERSITÄT DRESDEN, Dresden (DE)

(72) Inventors: Johannes SÖLLNER, Dresden (DE); Thomas STRAßNER, Dresden (DE)

(21) Appl. No.: 16/768,847

(22) PCT Filed: Nov. 9, 2018
(86) PCT No.: PCT/EP2018/080790

§ 371 Date: Apr. 5, 2021

(30) Foreign Application Priority Data
Dec. 1, 2017 (DE) 10 2017 128 629.2

(51) Int. Cl. C09K 11/06; C07F 15/00; H10K 85/30

(52) U.S. Cl. CPC C09K 11/06; C07F 15/0086; H10K 85/346; H10K 50/11

(57) ABSTRACT

The invention relates to novel platinum (II) complexes having NHC ligands, which are suitable for use in OLEDs, in particular as emitters or light emitting substances, the imidazole ring of the NHC ligand being of the mesoionic type. The invention also relates to OLEDs and/or light emitting layers containing complexes according to the invention, and to the use of complexes according to the invention in OLEDs.

### FIELD OF THE INVENTION

The present invention relates to platinum (II) complexes with N-heterocyclic carbene ligands (NHC ligands), organic light-emitting diodes (OLEDs) containing at least one corresponding complex, a device such as, for example, a stationary or mobile screen or a lighting means or illuminant, containing a corresponding OLED, and the use of the aforementioned complexes in OLEDs, for example as emitters, matrix materials, charge transport material and/or charge blocker.

### BACKGROUND OF THE INVENTION

In OLEDs, the property of materials is used to emit light when these materials are excited by electrical current. In particular, OLEDs are interesting as an alternative to cathode ray tubes and liquid crystal displays for the production of flat screens. Due to the very compact design and the intrinsically low power consumption, the device containing OLEDs is particularly suitable for mobile applications, e.g. for applications in mobile phones, laptops, etc., and for illumination.

The prior art discloses a variety of materials that emit light when excited by electrical current, including platinum (II) complexes with NHC ligands. In platinum (II) complexes with NHC ligands known from the prior art comprising an imidazole or imidazolylide ring, the carbene carbon atom is located on ring atom 2 of the imidazole ring, i.e. between two nitrogen atoms in the imidazole ring system of the NHC ligand, see A. Tronnier, S. Metz, G. Wagenblast, I. Muenster, T. Strassner, Dalton Trans. 2014, 43, 3297.

There are isolated transition metal complexes with so-called abnormally binding N-heterocyclic carbene ligands (aNHC ligands). In Hota et al., Adv. Synth. Catal. 2015, 357, 3162-3170 there is described a binuclear or dimeric palladium complex and its usability as a catalyst in the Heck reaction. Vijaykumar et al., Organometallics 2017, 36, 4753-4758 describe nickel catalysts provided with aNHC ligands for the hydro-heteroarylation of vinyl arenes. WO 2011/050003 A2 describes a platinum complex with a tridentate pincer ligand, wherein two of the “teeth” are formed by aNHC ligand groups. Thus in the case of platinum as the central atom, there is only room for a monodentate ligand.

The object of the invention is to provide alternative platinum (II) complexes with NHC ligands, which are suitable for use in OLEDs, in particular as emitters or as light emitting substances.

### DETAILED DESCRIPTION OF THE PREFERRED EMBODIMENTS

The above object is achieved by a platinum (II) complex of the following formula (I)

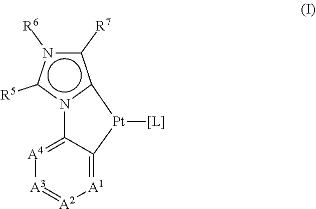

wherein
A¹ is N or CR¹,
A² is N or CR²
A³ is N or CR³,
A⁴ is N or CR⁴,
R¹ to R⁴ are each independently selected from H, a linear or branched, substituted or unsubstituted alkyl residue having 1 to 20 carbon atoms, wherein at least one carbon atom is optionally replaced by a heteroatom, a substituted one or unsubstituted cycloalkyl residue having 3 to 20 carbon atoms, wherein at least one carbon atom is optionally replaced by a heteroatom, a substituted or unsubstituted aryl residue having 6 to 30 carbon atoms, a substituted or unsubstituted heteroaryl residue having 5 to 18 carbon and/or heteroatoms, or a group having acceptor or donor properties, or R¹ and R², R² and R³, and/or R³ and R⁴ together with the atoms to which they are attached form a condensed aromatic ring system having 5 to 18 carbon and/or heteroatoms, the condensed aromatic ring system being substituted or unsubstituted,
R⁵ and R⁶ are each independently selected from a linear or branched, substituted or unsubstituted alkyl residue having 1 to 20 carbon atoms, wherein at least one carbon atom is optionally replaced by a heteroatom, a substituted or unsubstituted cycloalkyl residue having 3 to 20 carbon atoms, wherein at least one carbon atom is optionally replaced by a heteroatom, a substituted or unsubstituted aryl residue having 6 to 30 carbon atoms, a substituted or unsubstituted heteroaryl residue having 5 to 18 carbon and/or heteroatoms, or a group with acceptor or donor properties, and
R⁷ is selected from H, a linear or branched, substituted or unsubstituted alkyl residue having 1 to 20 carbon atoms, wherein at least one carbon atom is optionally replaced by a heteroatom, a substituted or unsubstituted cycloalkyl residue having 3 to 20 carbon atoms, wherein at least one carbon atom is optionally replaced by a heteroatom, a substituted or unsubstituted aryl residue having 6 to 30 carbon atoms, a substituted or unsubstituted heteroaryl residue having 5 to 18 carbon and/or heteroatoms, or a group with acceptor or donor properties, or R⁵ and R⁶ or R⁶ and R⁷ together with the atoms to which they are attached form a condensed aromatic ring system having 5 to 18 carbon and/or heteroatoms, wherein the condensed aromatic ring system is substituted or unsubstituted,
or R⁴ and R⁵ together with the atoms to which they are attached form a fused aromatic ring system having 6 to 18 carbon and/or heteroatoms, the fused aromatic ring system being substituted or unsubstituted,
L is a bidentate monoanionic ligand, and
   wherein
   R¹ to R⁷ and L each optionally carry one or more functional groups having donor or acceptor properties.

For the purposes of the present invention, terms such as aryl residue, heteroaryl residue, condensed aromatic ring system, alkyl residue, “substituted” and others have the following meanings:

Aryl residue: an aryl residue or an aryl group is a residue with a basic structure of 6 to 30 carbon atoms, preferably 6 to 18 carbon atoms, which is composed of one aromatic ring or more fused aromatic rings. Suitable basic structures are, for example, phenyl, naphthyl, anthracenyl or phenanthrenyl. This backbone can be unsubstituted, i.e. all carbon atoms that can be substituted carry hydrogen atoms or are substituted at one, more or all substitutable positions of the basic structure.

Preferably, the aryl residue or the aryl group is a C₆-aryl residue which is optionally substituted with at least one of the substituents mentioned below. The C₆-aryl residue particularly preferably has none, one, two, three or four of the substituents mentioned below.

“Substituted”: Substituted means that one or more hydrogen atoms have been replaced by other substituents. Suitable substituents are for example alkyl residues, preferably alkyl residues having 1 to 8 carbon atoms, particularly preferably methyl, ethyl, i-propyl or t-butyl, aryl residues, preferably C₆-aryl residues, which in turn can be substituted or unsubstituted, heteroaryl residues, preferably heteroaryl residues which contain at least one nitrogen atom, particularly preferably pyridyl residues, alkenyl residues, preferably alkenyl residues which carry a double bond, particularly preferably alkenyl residues having a double bond and 1 to 8 carbon atoms, or (functional) groups having donor or acceptor activity or properties. The aryl residues very particularly preferably carry substituents selected from the group consisting of alkylene, in particular methyl (—CH₃), F, disubstituted amine residues (—NR₂), thio groups (—SR) and alkoxy groups (—OR).

(Functional) groups having donor or acceptor activity or properties: Groups having donor activity or donor properties are to be understood as groups which have a positive inductive (+I) and/or positive mesomeric (+M) effect, and groups having an acceptor activity or acceptor properties are to be understood as groups which have a negative inductive (−I) and/or negative mesomeric (−M) effect. Suitable groups having donor or acceptor activity are halogen residues, preferably F, Cl, Br, particularly preferably F, alkoxy residues, aryloxy residues, carbonyl residues (—C(O)R), ester residues (—COOR), amine residues (—NH₂, —NHR, —NR₂), amide residues, CH₂F groups, CHF₂ groups, CF₃ groups, CN groups, NC groups, thio groups, SCN groups, NCS groups, the nitro or NO₂ group, boron diorganyl groups —BR₂, and diorganyl phosphane groups —PR₂, wherein R respectively stands for any organic residue.

Heteroaryl residue: A heteroaryl residue or a heteroaryl group is a residue which differs from the aryl residues mentioned above in that at least one carbon atom in the basic structure of the aryl residue is replaced by a heteroatom. Preferred heteroatoms are N, O and S. One or two carbon atoms of the basic structure of the aryl residue are very particularly preferably replaced by heteroatoms. The basic structure is particularly preferably selected from pyridyl, pyrimidyl, pyrazyl, triazyl, and five-membered heteroaromatics such as pyrrole, furan, thiophene, pyrazole, imidazole, triazole, oxazole, thiazole. The basic structure can be substituted at none, one, several or all substitutable positions of the basic structure.

Condensed aromatic ring system: A condensed aromatic ring system is a residue having a backbone or basic structure of 6 to 30 carbon atoms, preferably 6 to 18 carbon atoms, which is composed of one aromatic ring or several condensed aromatic rings. Suitable backbones or basic structures are, for example, phenyl, naphthyl, anthracenyl or phenanthrenyl. This backbone or basic structure can be unsubstituted, i.e. all carbon atoms that can be substituted carry hydrogen atoms or are substituted at one, more or all substitutable positions of the basic structure.

Alkyl residue: An alkyl residue or an alkyl group is a residue having 1 to 20 carbon atoms, preferably 1 to 10 carbon atoms, particularly preferably 1 to 8 carbon atoms. This alkyl residue can be branched or unbranched and optionally interrupted by one or more heteroatoms, preferably N, O or S. Furthermore, this alkyl residue can be substituted with one or more substituents mentioned above in connection with the aryl groups. The alkyl residue can also carry one or more aryl groups. All of the aryl groups listed above are suitable. Particularly preferred alkyl residues are selected from the group consisting of methyl, ethyl, i-propyl, n-propyl, i-butyl, n-butyl, t-butyl, sec-butyl, i-pentyl, n-pentyl, sec-pentyl, neo-pentyl, n-hexyl, hexyl and sec-hexyl. Methyl, i-propyl, tert-butyl and n-hexyl, in particular methyl, are very particularly preferred.

Cycloalkyl residue: A cycloalkyl residue or a cycloalkyl group is to be understood as a mono-, di- or tricyclic residue having 3 to 20 carbon atoms, preferably 3 to 10 carbon atoms, particularly preferably 3 to 8 carbon atoms. The cycloalkyl residue can optionally be interrupted by one or more heteroatoms, preferably N, O or S. The cycloalkyl residue can be unsubstituted or substituted, i.e. substituted with one or more of the substituents mentioned with regard to the aryl groups. It is also possible for the cycloalkyl residue to carry one or more aryl groups. All of the aryl groups listed above are suitable.

A¹ to A⁴ can each independently mean N, and several of A¹ to A⁴ can also mean N, wherein case A¹ and/or A³ preferably mean N.

Two or more of the residues R¹ to R⁴, which are adjacent, together with the atoms to which they are attached can form a condensed aromatic ring system, so that the bidentate NHC ligand of the Pt(II) complex according to the invention includes, for example, a benzofuryl, benzothiophenyl, dibenzofuryl, dibenzothiophenyl, naphthyl, anthracenyl, phenanthrenyl, fluorenyl or a carbazole group, as can be seen from the following exemplary formulae 1-27.

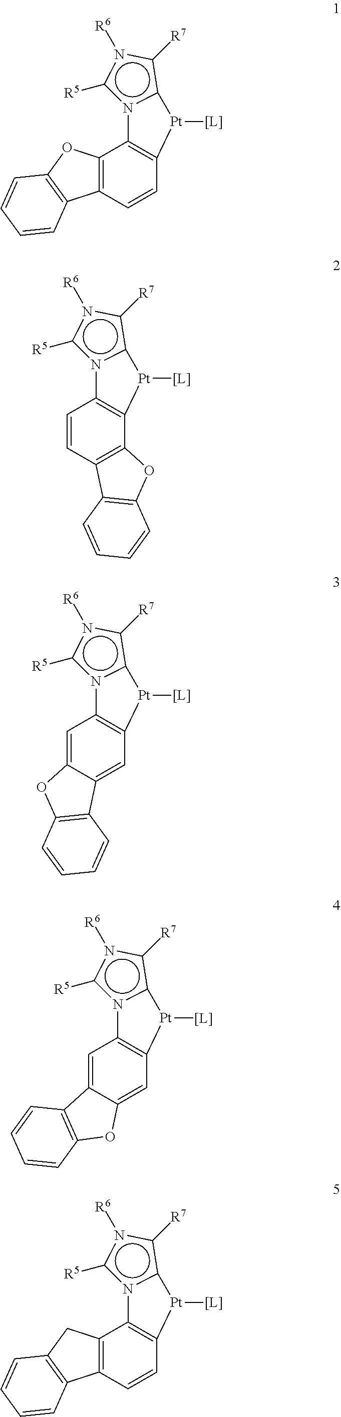

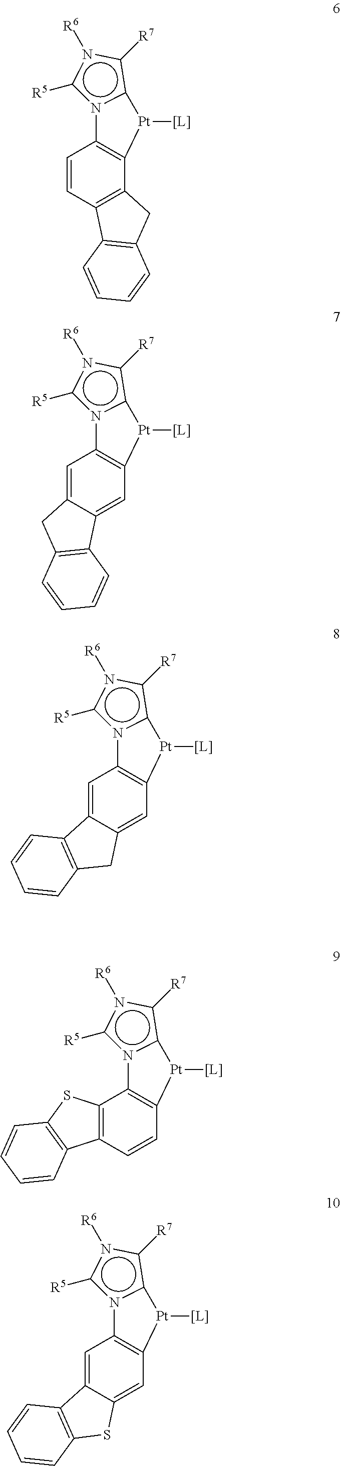

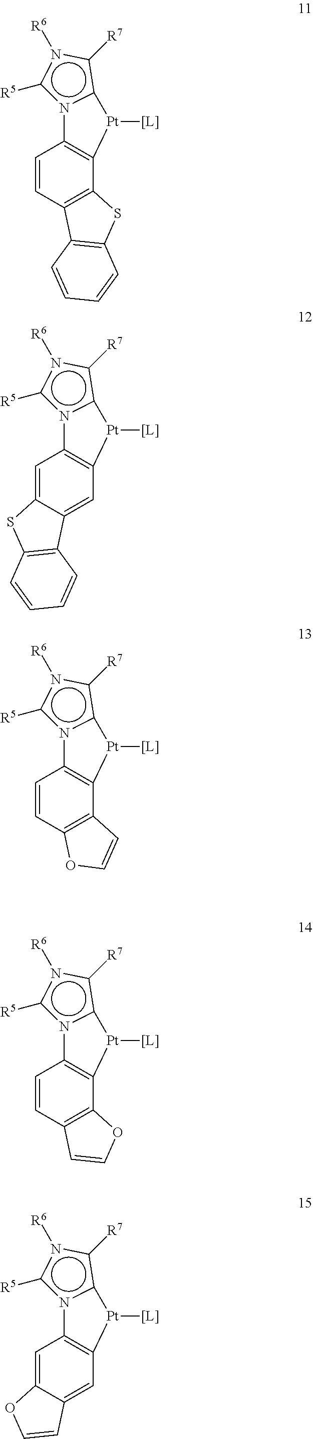

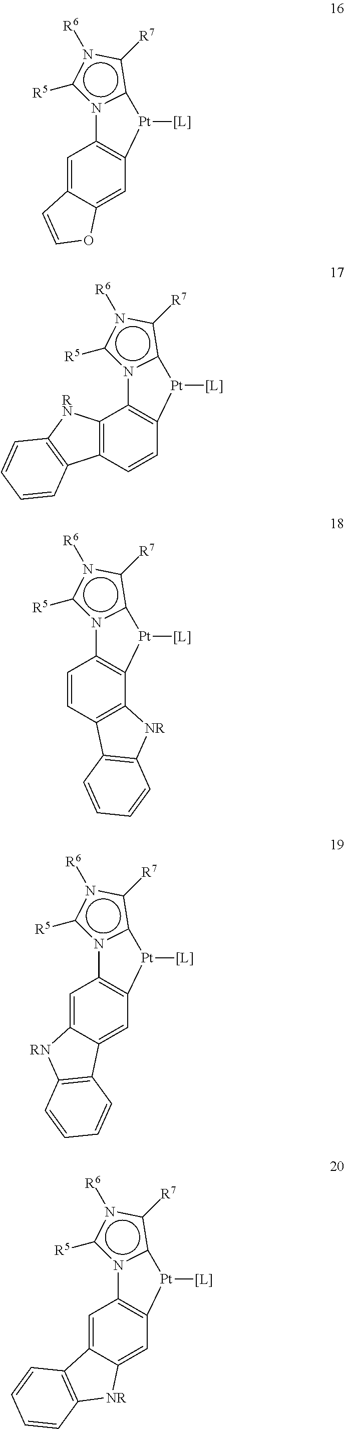

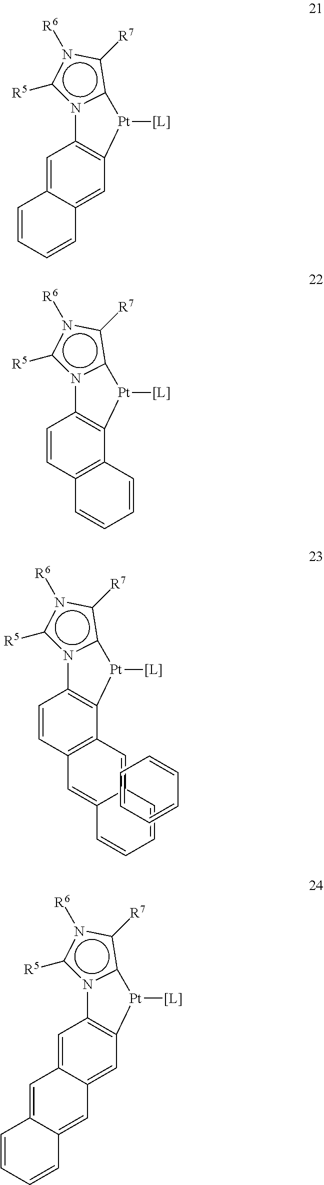

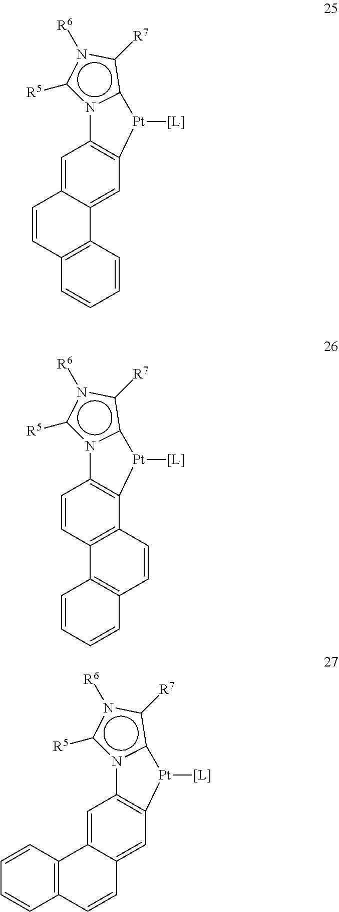

The above formulae represent:
Formulae 1 to 4 different possible isomers of complexes according to the invention having a dibenzofuran group,
formulae 5 to 8 different possible isomers of complexes according to the invention having a fluorene group,
formulae 9 to 12 different possible isomers of complexes according to the invention having a dibenzothiofuran group,
formulae 13 to 16 different possible isomers of complexes according to the invention having a benzofuran group,
formulae 17 to 20 different possible isomers of complexes according to the invention having a carbazole group,
formulae 21 to 22 different possible isomers of complexes according to the invention having a naphthalene group,
formulae 23 to 24 different possible isomers of complexes according to the invention having an anthracenyl group, and
formulae 25 to 27 different possible isomers of complexes according to the invention having a phenanthrene group.

Formulae 1 to 27 are only illustrative and should not be interpreted restrictively. Further condensed aromatic groups are also conceivable, which are also present in the form of different isomers. In particular, as mentioned above, the condensed aromatic ring systems can be substituted. All substituents already mentioned above are suitable as substituents, in particular substituents having donor or acceptor activity or effect.

R⁷ can be H. This is advantageous because the additional bidentate monoanionic ligand and [L] may then occupy a larger space.

In the complexes according to the invention, the carbene carbon atom of the NHC ligand which forms a bond to platinum is a ring atom of the imidazole ring. The carbene carbon atom is thus adjacent to a nitrogen atom and a carbon atom. The imidazole ring in the complexes according to the invention has a mesoionic character, i.e. no neutral mesomeric boundary structure can be formulated for the imidazole ring:

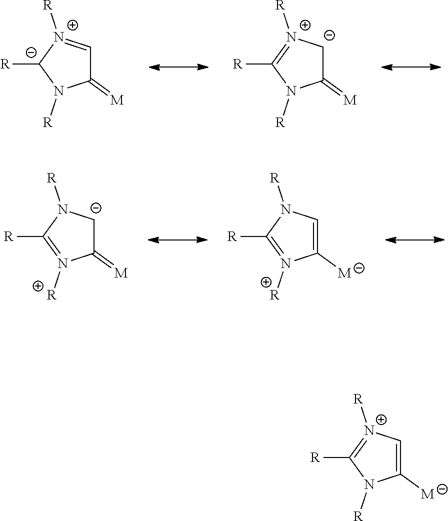

The mesoionic character means a change in the distribution of electrons on the NHC ligand compared to corresponding platinum complexes with conventional NHC ligands. Complexes according to the invention thus represent a new class of compounds which are particularly suitable for use in OLEDs.

In accordance with the invention, [L] is a bidentate monoanionic ligand. The bidentate ligand [L] binds twice to the central atom due to its bidentate nature. The platinum (II) complexes according to the invention thus have two bidentate ligands, are basically four-bonded and essentially square-planar.

The ligand L can advantageously and preferably be a bidentate monoanionic ligand of the formula (II):

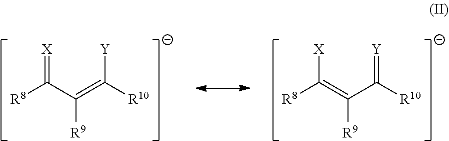

wherein
X and Y are independently selected from O, S or NR¹¹,
R⁸ and R¹⁰ are selected independently of one another from a linear or branched, substituted or unsubstituted alkyl residue having 1 to 20 carbon atoms, wherein at least one carbon atom is optionally replaced by a heteroatom, a substituted or unsubstituted cycloalkyl residue having 3 to 20 carbon atoms, wherein at least one carbon atom is optionally replaced by a heteroatom and which optionally carries one or more functional groups, a substituted or unsubstituted aryl residue having 6 to 30 carbon atoms, a substituted or unsubstituted heteroaryl residue having 5 to 18 carbon and/or heteroatoms,
R⁹ and R¹¹ are each independently selected from
   H, a linear or branched, substituted or unsubstituted alkyl residue having 1 to 20 carbon atoms, wherein at least one carbon atom is optionally replaced by a heteroatom, a substituted or unsubstituted cycloalkyl residue having 3 to 20 carbon atoms, wherein at least one carbon atom is optionally replaced by a heteroatom, a substituted or unsubstituted aryl residue having 6 to 30 carbon atoms, a substituted or unsubstituted heteroaryl residue having 5 to 18 carbon and/or heteroatoms, or
R⁸ and R⁹, R⁹ and R¹⁰, or R⁸ and R¹¹ and/or R¹⁰ and R¹¹ together with the atoms to which they are attached form a condensed aromatic ring system having 5 to 18 carbon and/or heteroatoms, the condensed aromatic ring system being substituted or unsubstituted, wherein
   R⁸ to R¹¹ each optionally carry one or more functional groups having donor or acceptor properties, and wherein,
   when both X and Y are NR¹¹, the two residues R¹¹ are identical or not identical.

In ligands of the above formula (II), X and Y are advantageously and preferably the same, particularly preferably in each case NR¹¹ or O.

In ligands of the preceding formula (II), R⁸ and R¹⁰ are advantageously and preferably in each case selected independently of one another from the group consisting of methyl, tert-butyl, mesityl, duryl, wherein mesityl (2,4,6-trimethylphenyl) and duryl (2,3,5,6-tetramethylphenyl) are particularly preferred.

The ligand [L] of the formula (II) is particularly advantageously and preferably constructed symmetrically in the sense that both X and Y and also R⁸ and R¹⁰ are identical.

Advantageously and preferably A¹ to A⁴ can be CR¹ to CR⁴, wherein at least two of R¹ to R⁴, together with the atoms to which they are attached, form a condensed aromatic ring system.

Furthermore preferred are platinum (II) complexes according to the invention wherein R⁷ is H.

Particularly preferred is that A¹ to A⁴ are CR¹ to CR⁴,

R¹, R², R³, R⁴, R⁷, R⁹ respectively are H,
R⁵ is selected from the group consisting of phenyl, 4-bromophenyl, 4-cyanophenyl,
R⁶ is selected from the group consisting of methyl or phenyl, and
R⁸, R¹⁰ are each independently selected from the group consisting of methyl, tert-butyl, mesityl, duryl, wherein mesityl and duryl are even more preferred.

Preferred platinum (II) complexes according to the invention are also the following individual compounds:

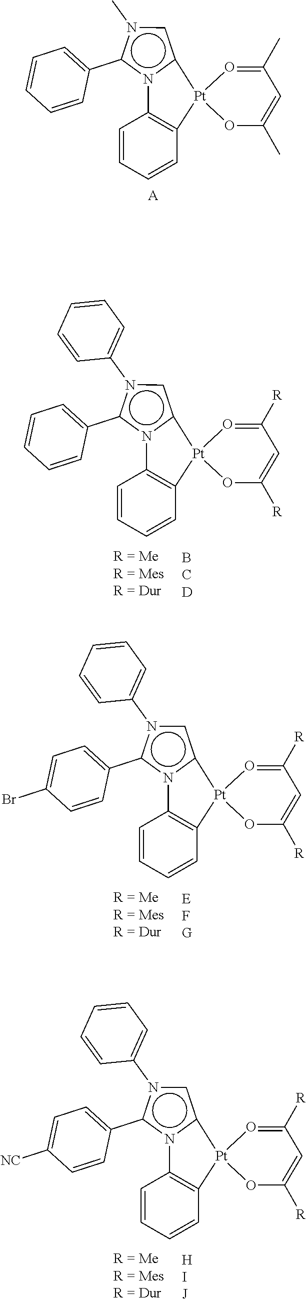

The complexes according to the invention are particularly suitable as emitter molecules in OLEDs. In particular, it is possible to provide corresponding complexes which show electroluminescence in all visible areas, in particular in the blue area of the electromagnetic spectrum. The complexes according to the invention are therefore suitable for use in industrially usable full-color displays or white OLEDs as illuminants or lighting means.

Other objects of the invention are accordingly
an OLED containing at least one platinum (II) complex according to the invention,
a light-emitting layer containing at least one platinum (II) complex according to the invention,
an OLED containing at least one light-emitting layer according to the invention,
a device containing an OLED according to the invention and/or an inventive a light-emitting layer according to the invention,
the use of a platinum (II) complex according to the invention in an OLED, and
the use of a platinum (II) complex according to the invention in an OLED, wherein the platinum (II) complex is being used as an emitter, matrix material, charge transport material and/or charge blocker.

Basically, OLEDs are made up of several layers, namely (i) anode, (ii) hole-transporting layer, (iii) light-emitting layer, (iv) electron-transporting layer, (v) cathode. OLEDs according to the invention may in addition contain further layers which are known to the person skilled in the art.

The metal-carbene complexes according to the invention are preferably used as emitter molecules in the light-emitting layer (iii).

The person skilled in the art is able to choose the structure of the OLEDs in such a way that it is optimally adapted to the complexes according to the invention and their specific use, preferably as an emitter, in the OLED.

The OLEDs according to the invention can be used in all devices in which electroluminescence is useful.

Corresponding devices are stationary screens, such as e.g. computer screens, television screens, screens in printers, kitchen appliances as well as billboards, lighting and notice boards. Mobile screens are e.g. screens in cell phones, laptops, photo cameras, vehicles and destination displays on buses and trains.

Suitable for the preparation of complexes according to the invention are processes for the preparation of platinum (II) complexes according to the invention by bringing suitable platinum compounds into contact with corresponding ligands or ligand precursors.

The ligands are on the one hand the NHC ligand, on the other hand monoanionic bidentate ligands [L], or their respective precursors.

Suitable platinum compounds in general are all Pt salts or complexes known to the person skilled in the art which have a sufficiently high reactivity under the reaction conditions according to the invention. Corresponding Pt salts or complexes are preferably selected from the group consisting of Pt(COD)Cl₂ (COD=cyclooctadiene), Pt(PPh₃)₂Cl₂, Pt(pyridine)₂Cl₂, Pt(NH₃)₂Cl₂, Pt(acac)₂, PtCl₂, K₂PtCl₄ and mixtures thereof. Particularly preferably Pt(COD)Cl₂ is used.

Suitable NHC ligands are compounds which, after reaction with Pt compounds yield the metal-carbene complexes of the above general formula (I).

Suitable NHC ligands can be used in the form of salts of the following general formula (III)

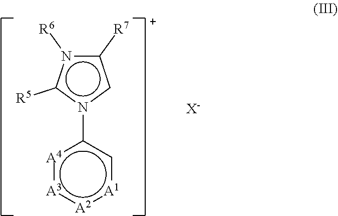

wherein A¹ to A⁴ and R¹ to R⁷ have the same meanings as described above in connection with formula (I), and
X⁻ denotes an anion, such as a halide ion, in particular Cl⁻, Br⁻, I⁻, particularly preferably I⁻, or BF₄⁻, PF₆⁻, N(SO₂CF₃)₂⁻, SbF₆⁻, ClO₄⁻, ½ SO₄²⁻, preferably BF₄⁻ or PF₆⁻, particularly preferably BF₄⁻.

Particularly preferred compounds of the general formula (III) which are used as ligand precursors in processes according to the invention are those which have the abovementioned preferred residues R¹, R², R³, R⁴, R⁵, R⁶, R⁷, and in particular those wherein X⁻ is BF₄⁻ or I⁻.

Various methods to build appropriately substituted imidazole rings are available to the person skilled in the art.

In order to prepare complexes according to the invention, for example starting from an aromatic amine a corresponding 1,2-substituted imidazole is first built. By way of an example, the aromatic amine (e.g. aniline), by reaction with an accordingly substituted aromatic nitrile (e.g. benzonitrile) in the presence of a base such as sodium hydride can be transformed into an amidine (e.g. into N-phenylbenzamidine in the case of reaction of aniline with benzonitrile). DMSO, for example, is suitable as a solvent. In addition to the exemplified aniline and the exemplified benzonitrile, a multitude of other aromatic amines and nitriles can be used in this reaction, including substituted aromatic amines and nitriles.

The resulting amidine can be reacted with chloroacetaldehyde, for example by dissolving in trichloromethane and heating to 70° C. for 24 hours, to yield an accordingly 1,2-substituted 1H-imidazole (in the case of N-phenylbenzamidine, for example, to yield 1,2-diphenyl-1H-imidazole).

1,2-disubstituted 1H-imidazoles can also be prepared in another way, for example by reaction of glyoxal with an aldehyde and an aromatic amine in the presence of ammonia or an ammonium salt, as described, for example, in a large number of reference examples in EP 2 254 871 B1 or in general in U.S. Pat. No. 6,177,575.

Further synthesis possibilities are known to the person skilled in the art.

By treatment with, for example, an alkyl iodide or other suitable compound, such as for example a diaryl iodonium salt, a 1,2-disubstituted 1H-imidazole can be provided with the desired residue on the ring atom 3 (nitrogen) of the imidazole ring, for example with a methyl group (by reaction with methyl iodide) or a substituted or unsubstituted aryl group (e.g. by reaction with an appropriate diaryl iodonium salt), the product being a salt of the above general formula (III) with a corresponding counterion (for example iodide or tetrafluoroborate).

Variously substituted diaryliodonium salts are e.g. described in Marcin Bielawski, Diaryliodonium Salts, Stockholm 2012 (ISBN: 978-91-7447-233-2, with further references). In the presence of copper (II) acetate monohydrate, for example, corresponding diaryliodonium tetrafluoroborates under stirring at 100° C. in DMF with the above mentioned 1,2-disubstituted 1H-imidazoles can be used to provide 1,2,3-trisubstituted imidazoles in the form of imidazolium salts, for example 1,2,3-triphenyl-IH-imididazolium tetrafluoroborate. The use of diaryl iodonium salts allows the introduction of very differently substituted aryl groups on ring atom 3 (nitrogen) of the imidazole ring.

The resulting compound of the formula (III) is then stirred, for example, in the presence of silver (I) oxide in DMF at 75° C. for 23 h, before being mixed with a suitable platinum-containing precursor (for example Pt(COD)Cl₂)) and being reacted first at room temperature (e.g. 3 h) and then at 120-130° C. (e.g. 21 h). Subsequent reaction with the precursor for the second monoanionic bidentate ligand, e.g. acetyl acetone, and potassium carbonate, followed by stirring at room temperature (e.g. 21 h) and then at 100° C. (e.g. 6 h) gives complexes according to the invention of the above mentioned formula (I).

The molar ratio of the starting materials in the process according to the invention is such that corresponding compounds of the general formula (I) are obtained, for example 1 to 10 eq., preferably 1 to 5 eq., particularly preferably 1 to 2 eq. NHC ligand precursor of formula (III), 1 eq. platinum compound, % eq. silver (I) oxide, and 1 to 10 eq., preferably 1 to 5 eq., particularly preferably 2 to 4 eq. ligand precursor of the monoanionic bidentate ligand L and potassium carbonate.

The process according to the invention is preferably carried out in a solvent. Suitable solvents are known to the person skilled in the art, for example ethers, cyclic ethers, ketones, polar solvents, preferably dichloromethane (DCM), dioxane, ethoxyethanol, butanone, dimethylformamide (DMF), or mixtures thereof.

The metal carbene complexes obtained can be worked up by methods known to those skilled in the art. For example, the residue remaining after removal of the solvent can first be cleaned with water and filtered, dried, extracted with DCM, purified by means of column chromatography, using, for example, iso-hexanes or iso-hexanes and ethyl acetate as the eluent or an eluent gradient from these, and the product so purified can then be washed with iso-hexanes and diethyl ether.

The precursor of the bidentate monoanionic ligand L can also be described by the following general formula (IV)

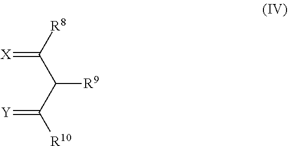

wherein X, Y, R⁸, R⁹, R¹⁰ have the same meanings as described above in relation to formula (II), it being clear to the person skilled in the art how to select X, Y, R⁸, R⁹, R¹⁰ so that the desired compound of the general formula (I) can be obtained.

Corresponding compounds of the formula (IV) are obtainable by processes known to the person skilled in the art or can be purchased. When X and Y are O, the represented formula (IV) corresponds to a keto tautomer and can consequently also be in the form of an enol tautomer. Acetyl acetone is particularly preferably used.

The present invention is described in more detail below on the basis of exemplary embodiments.

### EXAMPLES

The following examples, in particular the processes, reagents, reaction conditions, process parameters, equipment and the like described therein, serve to illustrate the present invention and are not to be interpreted as limiting the invention. The percentages given in the following examples are given in % by weight and any information on ratios is weight ratios, unless stated otherwise.

Complex compounds A to J described below, following the synthesis of NHC-ligands or ligand precuresors, were prepared under a protective gas atmosphere and in the absence of light. Dimethylformamide was used dried.

¹H, ¹³C and ¹⁹⁵Pt NMR spectra were measured on Bruker NMR Avance 300, Bruker DRX 500 and Bruker Avance 600 NMR NMR spectrometers. ¹H and ¹³ C NMR spectra were internally referenced using the solvent resonance (¹H: 7.26, ¹³C 77.0 for CDCl₃; ¹H: 2.50, ¹³C 39.43 for DMSO-d₆). ¹⁹⁵Pt NMR spectra were referenced externally in D₂O using potassium tetrachloridoplatinate (II) (PtCl₄²: −1617.2). Chemical shifts δ are given in ppm, coupling constants J in Hz. Elemental analyses were carried out using a Hekatech EA 3000 Euro Vector elemental analyzer. Melting points were determined using a Wagner and Munz PolyTherm A system and are not corrected. Emitter films were made by means of coating with a doctor blade a solution of the emitter in 10% by weight PMMA in dichloromethane onto a quartz substrate using a 60 μm doctor blade. The film was dried and the emission was measured under a nitrogen atmosphere. The dried film respectively contained 2% by weight of emitter. Excitation took place in a wavelength range of 250-400 nm (Xe lamp equipped with a monochromator), and emission was determined by means of a calibrated system for detecting the quantum yield (Hamamatsu, model C9920-02). With quantum yields >10%, the inaccuracy of the quantum yield is ±2%. The decay of the phosphorescence was measured by excitation with pulses from an EPLED (360 nm, 20 kHz) and time-resolved photon counting (TCSPC) with an Edinburgh Instruments mini-T device. Absorption spectra were measured on a Perkin Elmer Lambda 25 UV-VIS spectrometer.

Ligands or Ligand Precursors

### Preparation of N-phenylbenzamidine

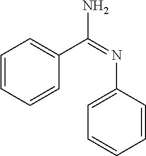 [SMILES: N/C(=N/c1ccccc1)c1ccccc1]

In a dried 50 ml round bottom flask, 0.360 g (15 mmol, 1.5 eq) sodium hydride are suspended in 5 ml DMSO and cooled to 0° C. 1.031 g (10 mmol) of benzonitrile and 1.118 g (12 mmol, 1.2 eq) of aniline are added. The resulting mixture is stirred at 0° C. for 1 h and then at room temperature for 24 h. After the reaction is complete, the mixture is cooled in an ice bath and 20 ml of water are added. The precipitate is taken up, washed with water and iso-hexanes and then dried in vacuo, yielding a light brown, amorphous solid (4.00 g, 67.9%). Melting point: 103° C.; ¹H NMR (300 MHz, CDCl₃): δ=7.84 (d, J=6.8 Hz, 2H, CHₐᵣₒₘ), 7.55-7.40 (m, 3H, CHₐᵣₒₘ), 7.35 (t, J=8.1, 7.6 Hz, 2H, CHₐᵣₒₘ), 7.07 (t, J=7.4 Hz, 1H, CHₐᵣₒₘ), 7.03-6.94 (m, 2H, CHₐᵣₒₘ), 4.86 (s, 2H, NH); ¹³C NMR (75 MHz, CDCl₃) δ 130.9 (CHₐᵣₒₘ), 129.7 (CHₐᵣₒₘ), 128.8 (CHₐᵣₒₘ), 127.1 (CHₐᵣₒₘ), 123.5 (CHₐᵣₒₘ), 122.0 (CHₐᵣₒₘ); Analysis calculated for C₁₃H₁₂N₂: C, 79.56; H, 6.16; N, 14.27; found: C, 79.57; H, 6.39; N, 14.17.

### Preparation of 1,2-diphenyl-1H-imidazole

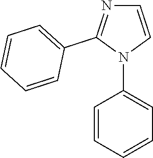 [SMILES: c1ccc(-c2nccn2-c2ccccc2)cc1]

3.925 g (20 mmol) N-phenylbenzamidine is placed under air atmosphere in a 250 ml round-bottomed flask equipped with a cooler. 6.280 g (40 mmol, 2 eq.) chloroacetaldehyde (50% by weight solution in water) is added and the mixture is dissolved in 70 ml of trichloromethane. The solution is heated to 70° C. for 24 h, then cooled to room temperature and treated with 30 ml of a saturated solution of NaHCO₃ in water. The phases are separated and the aqueous phase is extracted with dichloromethane (3×30 ml). The combined organic phase is dried with MgSO₄ and concentrated. The product is isolated by flash column chromatography using ethyl acetate as the eluent. After drying in vacuo, the product is obtained as a brown solid (3.37 g, 76.5%). Melting point: 73° C.; ¹H NMR (300 MHz, CDCl₃) δ 7.46-7.35 (m, 5H, CHₐᵣₒₘ), 7.33-7.20 (m, 6H, CHₐᵣₒₘ), 7.17 (d, J=1.3 Hz, 1H, CHₐᵣₒₘ); ¹³C NMR (75 MHz, CDCl₃) δ 146.8 (Cᵢ), 138.6 (Cᵢ), 130.1 (Cᵢ), 129.6 (CHₐᵣₒₘ), 128.8 (CHₐᵣₒₘ), 128.8 (CHₐᵣₒₘ), 128.6 (CHₐᵣₒₘ), 128.4 (CHₐᵣₒₘ), 128.3 (CHₐᵣₒₘ), 126.0 (CHₐᵣₒₘ), 123.0 (CHₐᵣₒₘ); analysis calculated for C₁₅H₁₂N2: C, 81.79; H, 5.49; N, 12.72; found: C, 81.75; H, 5.62; N, 12.46.

### Preparation of 3-methyl-1,2-diphenyl-1H-imidazoliumiodide

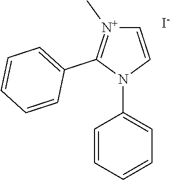 [SMILES: C[n+]1ccn(-c2ccccc2)c1-c1ccccc1 ; [I-]]

Under an air atmosphere, a pressure tube is loaded with 1.101 g (5 mmol) of 1,2-diphenyl-1H-imidazole and 1.434 g (10 mmol, 2 eq) of methyl iodide. The reagents are dissolved in 3 ml THF and stirred at 110° C. for 24 h. The mixture is cooled to room temperature, diethyl ether is added and the precipitate is taken up. The solid is washed with THF (2×5 ml) and diethyl ether (3×5 ml) and dried in vacuo. The product is obtained as a somewhat yellow powder (1.50 g, 82.8%). Melting point: 243° C.; ¹H NMR (300 MHz, DMSO-d₆) δ 8.18 (d, J=2.1 Hz, 1H, CHₐᵣₒₘ), 8.12 (d, J=2.1 Hz, 1H, CHₐᵣₒₘ), 7.66-7.46 (m, 8H, CHₐᵣₒₘ), 7.46-7.35 (m, 2H, CHₐᵣₒₘ), 3.79 (s, 3H, NCH₃); ¹³C NMR (75 MHz, DMSO-d₆) δ 144.3 (Cᵢ), 135.1 (Cᵢ), 132.1 (CHₐᵣₒₘ), 130.9 (CHₐᵣₒₘ), 130.1 (CHₐᵣₒₘ), 129.7 (CHₐᵣₒₘ), 129.1 (CHₐᵣₒₘ), 126.2 (CHₐᵣₒₘ), 123.7 (CHₐᵣₒₘ), 123.5 (CHₐᵣₒₘ), 121.4 (Cᵢ), 35.89 (NCH₃); analysis calculated for C₁₆H₁₅IN₂: C, 53.06; H, 4.17; N, 7.73; found: C, 52.83; H, 3.81; N, 7.75.

### Preparation of 1,2,3-triphenyl-1H-imidazoliumtetrafluoroborate

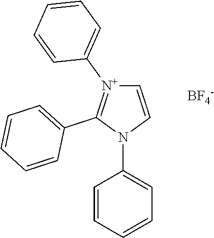 [SMILES: c1ccc(-c2n(-c3ccccc3)cc[n+]2-c2ccccc2)cc1 ; "BF4-"]

1.652 g (7.5 mmol) of 1,2-diphenyl-1H-imidazole, 3.311 g (9 mmol, 1.2 eq) of diphenyliodonium tetrafluoroborate and 0.075 g (0.375 mmol, 0.05 eq) of copper (II) acetate monohydrate are placed in a Schlenk tube and dissolved in 20 ml DMF. The mixture is stirred at 100° C. for 16 h, then cooled to room temperature and all volatile substances are removed in vacuo. The product is crystallized from hot methanol and obtained in the form of colorless to light brown crystals (2.55 g, 88.5%). Melting point: 274° C.; ¹H NMR (300 MHz, DMSO-d₆) δ 8.43 (s, 2H, CHₐᵣₒₘ), 7.58-7.44 (m, 10H, CHₐᵣₒₘ), 7.44-7.27 (m, 5H, CHₐᵣₒₘ); ¹³C NMR (75 MHz, DMSO-d₆) δ 144.5 (Cᵢ), 135.0 (Cᵢ), 131.8 (CHₐᵣₒₘ), 131.2 (CHₐᵣₒₘ), 130.3 (CHₐᵣₒₘ), 129.7 (CHₐᵣₒₘ), 128.6 (CHₐᵣₒₘ), 126.4 (CHₐᵣₒₘ), 124.0 (CHₐᵣₒₘ), 121.6 (Cᵢ); ¹⁹F NMR (282 MHz, DMSO-d₆) 5-148.8 (s, BF₄⁻), —148.9 (s, BF₄⁻); analysis calculated for C₂₁H₁₇BF₄N₂: C, 65.65; H, 4.46; N, 7.29; found: C, 65.75; H, 4.74; N, 7.33.

### Preparation of 4-bromo-N-phenylbenzamidine

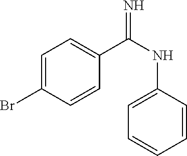 [SMILES: N=C(Nc1ccccc1)c1ccc(Br)cc1]

0.720 g (30 mmol, 1.5 eq) of sodium hydride are placed in a heated 100 ml Schlenk flask under an argon atmosphere and suspended in 5 ml of DMSO. 3.640 g (20 mmol) of 4-bromobenzonitrile and 2.235 g (24 mmol, 1.2 eq) of aniline are added with cooling in an ice bath. The reaction is stirred overnight at room temperature and then three times the volume of water is added. The mixture is filtered, the filter cakes washed with water, then dissolved in DCM and dried over magnesium sulphate. The organic phase is spun in to dryness, the solid recrystallized in a mixture of iso-hexane and ethyl acetate. After filtration, washing with a little diethyl ether and drying in vacuo, the product is obtained as a yellow solid. Yield 1.92 g (35%); melting point 140° C.; molecular formula: C₁₃H₁₁BrN₂; molar mass 275.15 g/mol; ¹H-NMR (300 MHz, CDCl₃) δ (ppm)=7.73 (d, J=8.2 Hz, 2H, CHₐᵣₒₘ), 7.57 (dt, J=8.6, 2.0 Hz, 2H, CHₐᵣₒₘ), 7.36 (t, J=7.9 Hz, 2H, CHₐᵣₒₘ), 7.09 (tt, J=7.4, 1.1 Hz, 1H, CHₐᵣₒₘ), 7.02-6.92 (m, 2H, CHₐᵣₒₘ), 4.94 (bs, 2H, NH₂); ¹³C-NMR (75 MHz, CDCl₃) δ (ppm)=131.9 (CHₐᵣₒₘ), 129.74 (CHₐᵣₒₘ), 128.7 (Cᵢ), 125.3 (CHₐᵣₒₘ), 123.6 (CHₐᵣₒₘ), 121.8 (CHₐᵣₒₘ) (missing quaternary C resonances not visible in the spectrum). Elemental analysis calculated: C 56.75%; H 4.03%; N 10.18%; found 56.77%; H 4.02%; N 10.18%.

### Preparation of 2-(4-bromophenyl)-1-phenyl-1H-imidazole

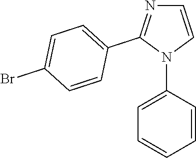 [SMILES: Brc1ccc(-c2nccn2-c2ccccc2)cc1]

3.027 g (11 mmol) of 4-bromo-N-phenylbenzamidine and 3.454 g (22 mmol, 2 eq) of aqueous chloroacetaldehyde solution (50%) are dissolved in 35 ml of chloroform in a 100 ml flask. The mixture is refluxed at 70° C. for 24 h and then saturated sodium hydrogen carbonate solution is added. The phases are separated and the aqueous phase is extracted with DCM (3×30 ml). The combined organic phase is dried over magnesium sulphate and the solvent is removed in vacuo. The crude product is purified by column chromatography with the eluent mixture of iso-hexane/ethyl acetate (1:2). After drying in vacuo, the product is obtained as a light brown solid. Yield 2.87 g (87%); Melting point 119° C.; Molecular formula C₁₅H₁₁BrN₂; Molar mass 299.17 g/mol; ¹H NMR (300 MHz, CDCl₃) δ=7.47-7.35 (m, 5H, CHₐᵣₒₘ), 7.31-7.19 (m, 5H, CHₐᵣₒₘ), 7.19-7.15 (m, 1H, CHₐᵣₒₘ); ¹³C NMR (75 MHz, CDCl₃); δ=145.6 (Cᵢ), 138.3 (Cᵢ), 131.5 (CHₐᵣₒₘ), 130.1 (CHₐᵣₒₘ), 129.8 (CHₐᵣₒₘ), 129.0 (CHₐᵣₒₘ), 128.6 (CHₐᵣₒₘ), 126.0 (CHₐᵣₒₘ), 123.3 (CHₐᵣₒₘ), 123.0 (Cᵢ) (the missing C resonance is not resolved in the spectrum). Elemental analysis calculated: C 60.22%; H 3.71%; N 9.36%; found: C 60.32%; H 3.64%; N 9.32%.

### Preparation of 2-(4-bromophenyl)-1,3-diphenyl-1H-imidazolium tetrafluoroborate

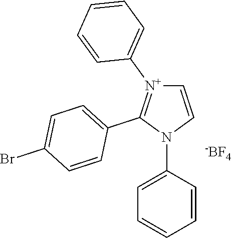

1.496 g (5 mmol) of 2-(4-bromophenyl)-1-phenyl-1H-imidazole, 2.759 g (7.5 mmol, 1.5 eq) of diphenyliodonium tetrafluoroborate and 0.050 g (0.25 mmol, 0.05 eq) of copper (II) acetate monohydrate are placed in a Schlenk tube and dissolved in 20 ml of DMF. The mixture is stirred at 100° C. for 18 h and the solvent is then removed in vacuo. The residue is dissolved in a little dichloromethane and left to crystallize overnight. The solid is filtered and washed with ether. After drying in vacuo, the product is obtained as a brownish solid.

Yield 1.32 g (57%); melting point 222° C.; molecular formula C₂₁H₁₆BBrF₄N₂; Molar mass 463.08 g/mol¹H NMR (600 MHz, DMSO-d₆) δ=8.43 (s, 1H, CHₐᵣₒₘ), 7.62-7.58 (m, 1H, CHₐᵣₒₘ), 7.58-7.52 (m, 3H, CHₐᵣₒₘ), 7.52-7.46 (m, 2H, CHₐᵣₒₘ), 7.37-7.31 (m, 1H, CHₐᵣₒₘ); ¹³C NMR (151 MHz, DMSO-d₆) δ=143.5 (Cᵢ), 134.8 (Cᵢ), 133.2 (CHₐᵣₒₘ), 131.8 (CHₐᵣₒₘ), 130.4 (CHₐᵣₒₘ), 129.8 (CHₐᵣₒₘ), 126.3 (CHₐᵣₒₘ), 125.9 (Cᵢ), 124.1 (CHₐᵣₒₘ), 120.8 (Cᵢ). Elemental analysis calculated: C 54.47%; H 3.48%; N 6.05%; found: C 54.59%; H 3.44%; N 6.19%.

### Preparation of 4-cyano-N-phenylbenzamidine

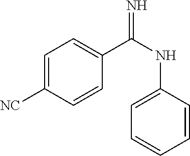 [SMILES: N#Cc1ccc(C(=N)Nc2ccccc2)cc1]

0.720 g (30 mmol, 1.5 eq) of sodium hydride are placed in a heated 100 ml Schlenk flask under an argon atmosphere and suspended in 10 ml of DMSO. While cooling in an ice bath, 2.563 g (20 mmol) of terephthalic acid dinitrile and 2.235 g (24 mmol, 1.2 eq) of aniline are added. The reaction is stirred overnight at room temperature and then three times the volume of water is added. The mixture is filtered, the filter cake washed with water, then dissolved in DCM and dried over magnesium sulphate. The organic phase is rotary dried, the solid recrystallized in acetonitrile. After filtration, washing with a little diethyl ether and drying in vacuo, the product is obtained as a yellow solid.

Yield 1.83 g (41%); Melting point 190° C.; Molecular formula C₁₄H₁₁N3; molar mass 221.26 g/mol; ¹H NMR (500 MHz, DMSO-d₆) 5=8.12 (d, J=8.1 Hz, 2H, CHₐᵣₒₘ), 7.91 (d, J=8.2 Hz, 2H, CHₐᵣₒₘ), 7.32 (t, J=7.6 Hz, 2H, CHₐᵣₒₘ), 7.00 (t, J=7.4 Hz, 1H, CHₐᵣₒₘ), 6.86 (d, J=7.8 Hz, 2H, CHₐᵣₒₘ), 6.48 (s, 2H, NH₂); ¹³C NMR (126 MHz, DMSO-d₆) δ=152.7 (Cᵢ), 150.1 (Cᵢ), 140.3 (Cᵢ), 132.2 (CHₐᵣₒₘ), 129.4 (CHₐᵣₒₘ), 128.1 (CHₐᵣₒₘ), 122.4 (CHₐᵣₒₘ), 121.6 (CHₐᵣₒₘ), 118.8 (Cᵢ), 112.5 (Cᵢ). Elemental analysis calculated: C 76.00%; H 5.01%; N 18.99%; found: C 75.62%; H 4.80%; N 18.64%.

### Preparation of 2-(4-cyanophenyl)-1-phenyl-1H-imidazole

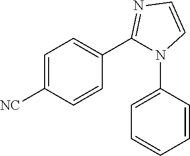 [SMILES: N#Cc1ccc(-c2nccn2-c2ccccc2)cc1]

2.213 g (10 mmol) of 4-cyano-N-phenylbenzamidine and 3.140 g (20 mmol, 2 eq) of aqueous chloroacetaldehyde solution (50%) are dissolved in 50 ml of chloroform in a 100 ml flask. The mixture is refluxed at 70° C. for 24 h and then saturated sodium hydrogen carbonate solution is added. The phases are separated and the aqueous phase is extracted with DCM (3×30 ml). The combined organic phase is dried over magnesium sulphate and the solvent is removed in vacuo. The crude product is purified by column chromatography with the eluent mixture of iso-hexane/ethyl acetate (1:2). After drying in vacuo, the product is obtained as a light brown solid.

Yield 1.50 g (61%); Melting point 113° C.; Molecular formula C₁₆H₁₁N₃; molar mass 245.28 g/mol; ¹H NMR (300 MHz, CDCl₃) δ=7.61-7.54 (m, 4H), 7.54-7.46 (m, 3H), 7.34 (d, J=1.3 Hz, 1H), 7.31-7.23 (m, 3H); ¹³C NMR (75 MHz, CDCl₃) δ=144.5 (Cᵢ), 137.9 (Cᵢ), 134.4 (Cᵢ), 131.9 (CHₐᵣₒₘ), 129.8 (2 CHₐᵣₒₘ), 128.8 (CHₐᵣₒₘ), 128.7 (CHₐᵣₒₘ), 125.8 (CHₐᵣₒₘ), 124.2 (CHₐᵣₒₘ), 118.5 (Cᵢ), 111.6 (Cᵢ); elemental analysis calculated: C 78.35%; H 4.52%; N 17.13%; found 78.54%; H 4.63%; N 16.75%.

### Preparation of 2-(4-cyanophenyl)-1,3-diphenyl-1H-imidazolium tetrafluoroborate

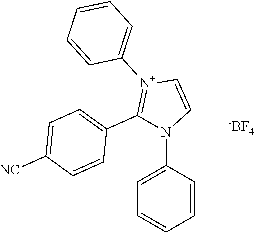

In a Schlenk tube, 1.226 g (5 mmol) of 2-(4-cyanophenyl)-1-phenyl-1H-imidazole, 2.649 g (7.2 mmol, 1.44 eq) diphenyliodonium tetrafluoroborate and 0.050 g (0.25 mmol, 0.05 eq) copper (II) acetate monohydrate and dissolved in 20 ml of DMF. The mixture is stirred at 100° C. for 18 h and the solvent is then removed in vacuo. The residue is taken up in dichloromethane, the solid is filtered and washed with DCM (3×5 ml). After drying in vacuo, the product is obtained as a brownish solid.

Yield 1.73 g (85%); Melting point 174° C.; molecular formula C₂₂H₁₆BF₄N₃; molar mass 409.19 g/mol; ¹H NMR in DMSO-d₆ (300 MHz) 5=8.48 (s, 2H, CHₐᵣₒₘ), 7.87 (d, J=8.4 Hz, 2H, CHₐᵣₒₘ), 7.61 (d, J=8.4 Hz, 2H, CHₐᵣₒₘ), 7.58-7.52 (m, 6H, CHₐᵣₒₘ), 7.52-7.45 (m, 4H, CHₐᵣₒₘ); ¹³C NMR in DMSO-d₆ (75 MHz) δ=142.7 (Cᵢ), 134.6 (Cᵢ), 132.4 (CHₐᵣₒₘ), 132.3 (CHₐᵣₒₘ), 130.6 (CHₐᵣₒₘ), 129.9 (CHₐᵣₒₘ), 126.3 (CHₐᵣₒₘ), 126.2 (Cᵢ), 124.4 (CHₐᵣₒₘ), 117.5 (Cᵢ), 114.3 (Cᵢ). Elemental analysis calculated: C 64.58%; H 3.94%; N 10.27%; found 64.66%; H 3.94%; N 10.27%.

### Carbene Platinum (II) Complexes

### Complex A

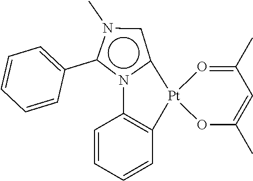

0.580 g (1.6 mmol) of 3-methyl-1,2-diphenylimidazolium iodide and 0.185 g (0.8 mmol, 0.5 eq) of silver (I) oxide are suspended in 40 ml of dry DMF in a Schlenk tube and stirred at 75° C. for 23 h. At room temperature, 0.599 g (1.6 mmol, 1 eq) Pt(COD)Cl₂ are added and the reaction mixture is stirred first at room temperature for 3 h, then at 130° C. for 21 h. After cooling to room temperature, 0.641 g (6.4 mmol, 4 eq) of acetylacetone and 0.885 g (6.4 mmol, 4 eq) of potassium carbonate are added, and the mixture is stirred at room temperature for 21 h and then at 100° C. for 6 h. After removing the solvents in vacuo, the residue is washed with water, filtered and the filter cake is dried at 60° C. overnight. The solid is extracted with DCM and then eluted by column chromatography with a gradient of iso-hexane/ethyl acetate (2:1) to pure ethyl acetate. The solid obtained is then washed with iso-hexane in an ultrasonic bath (3×5 ml). After drying in vacuo, the product is obtained as a brown solid (155 mg, 18%).

Melting point: 253° C.

¹H NMR (300 MHz, CDCl₃)

δ=7.84 (t, J=13.8 Hz, 1H, PtCCH), 7.74-7.57 (m, 3H, CH_{para/meta} von C2-Ph), 7.46 (d, J=6.5 Hz, 2H, CHₒᵣₜₕₒ von C2-Ph), 6.91 (t, J=7.5 Hz, 1H, CHₚₐᵣₐ von N3-Ph), 6.86 (s, 1H, NCH), 6.63 (t, J=7.2 Hz, 1H, CHₘₑₜₐ von N3-Ph), 6.18 (d, J=8.0 Hz, 1H, CHₒᵣₜₕₒ von N3-Ph), 5.43 (s, 1H, COCH), 3.47 (s, 3H, NCH₃), 2.00 (s, 3H, COCH₃), 1.95 (s, 3H, COCH₃). ¹³C NMR (75 MHz, CDCl₃)

δ=184.9 (CO), 184.8 (CO), 148.2 (NCCH von N3-Ph), 139.5 (NCN), 133.1 (PtCCH), 132.1 (PtCN), 131.9 (CHₚₐᵣₐ of C2-Ph), 130.6 (CHₒᵣₜₕₒ of C2-Ph), 130.0 (CHₘₑₜₐ of C2-Ph), 129.6 (PtCCN), 125.5 (CHₚₐᵣₐ of N3-Ph), 124.6 (NCCH of C2-Ph), 122.4 (CHₘₑₜₐ of N3-Ph), 120.3 (NCH), 113.0 (CHₒᵣₜₕₒ of N3-Ph), 102.0 (COCH), 34.4 (NCH₃), 28.3 (COCH₃), 28.1 (COCH₃).

¹⁹⁵Pt NMR (64 MHz, CDCl₃)

δ=−3369.4 (s).

Elemental analysis calculated for C₂₁H₂₀N₂O₂Pt 0.16 CH₂Cl₂: C, 47.97; H, 3.79; N, 5.18; Found: C, 47.25; H, 3.48; N, 5.29.

### Complex B

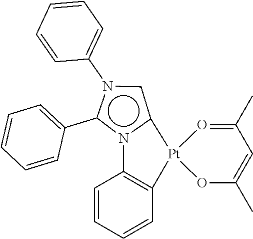

In a Schlenk tube, 0.615 g (1.6 mmol) of 1,2,3-triphenylimidazolium tetrafluoroborate and 0.185 g (0.8 mmol, 0.5 eq) of silver (1) oxide are suspended in 40 ml of dry DMF and stirred initially at 80° C. for 20 h, then at 95° C. for 4 h. 0.599 g (1.6 mmol, 1 eq) Pt(COD)Cl₂ are added at room temperature and the reaction mixture is first stirred at room temperature for 3 h and then at 125° C. for 21 h. After cooling to room temperature, 0.320 g (3.2 mmol, 2 eq) of acetylacetone and 0.442 g (3.2 mmol, 2 eq) of potassium carbonate are added and the mixture is stirred at room temperature for 21 h and then at 100° C. for 6 h. After removing the solvents in vacuo, the residue is washed with water, filtered and the filter cake is dried at 60° C. overnight. The solid is extracted with DCM and then eluted by means of column chromatography separation with a gradient of iso-hexane/ethyl acetate in a ratio of 3:1 to 2:1. The solid obtained is then washed with iso-hexane and diethyl ether in an ultrasonic bath (3×5 ml each). After drying in vacuo, the product is obtained as a light brown solid (463 mg, 49%).

¹H NMR (600 MHz, CDCl₃)

δ=7.96-7.79 (m, 1H, PtCCH), 7.53 (tt, J=7.5, 1.9 Hz, 1H, CHₚₐᵣₐ of C2-Ph), 7.47 (t, J=7.9, 7.3 Hz, 2H, CHₘₑₜₐ of C2-Ph), 7.40-7.30 (m, 5H, CHₒᵣₜₕₒ of C2-Ph and CH_{meta/para} of N3-Ph), 7.21-7.13 (m, 2H, CHₒᵣₜₕₒ of N3-Ph), 7.11 (s, 1H, NCH), 6.97 (td, J=7.4, 1.2 Hz, 1H, CHₚₐᵣₐ of N1-Ph), 6.70-6.64 (m, 1H, CHₘₑₜₐ of N1-Ph), 6.31 (dd, J=8.1, 1.2 Hz, 1H, CHₒᵣₜₕₒ of N1-Ph), 5.44 (s, 1H, COCH), 2.02 (s, 3H, COCH₃), 1.94 (s, 3H, COCH₃).

¹³C NMR (75 MHz, CDCl₃)

δ=185.1 (CO), 184.9 (CO), 148.0 (NCCH of N1-Ph), 139.4 (NCN), 136.3 (NCCH of N3-Ph), 133.2 (PtCCH), 132.4 (PtCN), 131.6 (CHₚₐᵣₐ of C2-Ph), 131.0 (CHₒᵣₜₕₒ of C2-Ph), 130.1 (PtCCN), 129.6 (CHₘₑₜₐ of C2-Ph/CHₚₐᵣₐ of N3-Ph), 129.5 (CHₘₑₜₐ of C2-Ph/CHₚₐᵣₐ of N3-Ph), 129.3 (CHₚₐᵣₐ of N3-Ph), 126.0 (CHₒᵣₜₕₒ of N3-Ph), 125.9 (CHₚₐᵣₐ of N1-Ph), 124.6 (NCCH of C2-Ph), 122.6 (CHₘₑₜₐ of N1-Ph), 120.9 (NCH), 113.7 (CHₒᵣₜₕₒ of N1-Ph), 102.1 (COCH), 28.3 (COCH₃), 28.1 (COCH₃).

¹⁹⁵Pt NMR (64 MHz, CDCl₃)

δ=−3371.6 (s).

Elemental analysis calculated for C₂₆H₂₂N₂O₂Pt: C, 52.97; H, 3.76; N, 4.75; Found: C, 52.65; H, 3.57; N, 4.75.

### Complex C

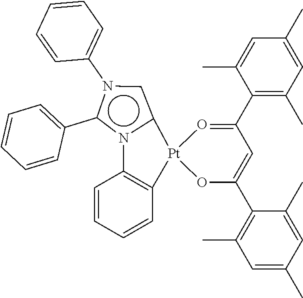

In a Schlenk tube, 0.615 g (1.6 mmol) of 1,2,3-triphenylimidazolium tetrafluoroborate and 0.185 g (0.8 mmol, 0.5 eq) of silver (I) oxide are suspended in 40 ml of dry DMF and stirred at 75° C. for 24 h. At room temperature, 0.599 g (1.6 mmol, 1 eq) Pt(COD)Cl₂ are added and the reaction mixture is first stirred at room temperature for 3 h and then at 125° C. for 21 h. After cooling to room temperature 0.987 g (3.2 mmol, 2 eq) bis-1,3-(2,4,6-trimethylphenyl)propane-1,3-dione and 0.359 g (3.2 mmol, 2 eq) potassium tert-butanolate are added and the mixture is first stirred at room temperature for 21 h, then at 100° C. for 6 h. After removing the solvents in vacuo, the residue is washed with water, filtered and the filter cake is dried at 60° C. overnight. The solid is extracted with DCM and then eluted by column chromatography with a gradient of iso-hexane/DCM in a ratio of 1:2. The solid obtained is then washed with iso-hexane in an ultrasonic bath (3×5 ml each). After drying in vacuo, the product is obtained as a yellow solid (116 mg, 9%).

Melting point: 312° C.

¹H NMR (300 MHz, CDCl₃)

δ=7.95-7.67 (m, 1H, CHₐᵣₒₘ), 7.60-7.41 (m, 3H CHₐᵣₒₘ), 7.39-7.24 (m, 5H, CHₐᵣₒₘ), 7.13 (dd, J=7.6, 2.1 Hz, 2H, CHₐᵣₒₘ), 7.08 (s, 1H, CHₐᵣₒₘ), 6.93-6.83 (m, 3H, CHₐᵣₒₘ), 6.81 (s, 2H, CHₐᵣₒₘ), 6.73-6.56 (m, 1H, CHₐᵣₒₘ), 6.30 (dd, J=8.1, 1.2 Hz, 1H, CHₐᵣₒₘ), 5.60 (s, 1H, COCH), 2.39 (s, 6H, CCH₃), 2.36 (s, 6H, CCH₃), 2.29 (s, 3H, CCH₃), 2.26 (s, 3H, CCH₃).

¹³C NMR (75 MHz, CDCl₃)

δ=184.6 (CO), 184.1 (CO), 147.9 (Cᵢ), 140.2 (Cᵢ), 140.1 (Cᵢ), 139.3 (Cᵢ), 137.3 (Cᵢ), 137.3 (Cᵢ), 136.1 (Cᵢ), 134.3 (Cᵢ), 134.1 (Cᵢ), 133.7 (CHₐᵣₒₘ), 132.0 (Cᵢ), 131.6 (CHₐᵣₒₘ), 130.9 (CHₐᵣₒₘ), 129.8 (Cᵢ), 129.5 (CHₐᵣₒₘ), 129.2 (CHₐᵣₒₘ), 128.2 (CHₐᵣₒₘ), 128.1 (CHₐᵣₒₘ), 125.9 (CHₐᵣₒₘ), 125.2 (CHₐᵣₒₘ), 124.6 (Cᵢ), 122.7 (CHₐᵣₒₘ), 121.3 (CHₐᵣₒₘ), 115.2 (CHₐᵣₒₘ), 113.6 (CHₐᵣₒₘ), 107.0 (CHₐᵣₒₘ), 21.2 (CCH₃), 21.2 (CCH₃), 20.0 (CCH₃), 19.9 (CCH₃).

¹⁹⁵Pt NMR (64 MHz, CDCl₃)

δ=−3306.7 (s).

Elemental analysis calculated for C₄₂H₃₃N₂O₂Pt: C, 63.23; H, 4.80; N, 3.51; Found: C, 63.50; H, 4.90; N, 3.47.

### Complex D

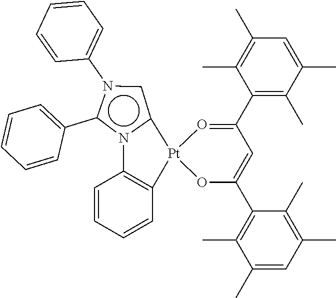

In a Schlenk tube, 0.307 g (0.8 mmol) of 1,2,3-triphenylimidazolium tetrafluoroborate and 0.093 g (0.4 mmol, 0.5 eq) of silver (I) oxide are suspended in 20 ml of dry DMF and 24 at 75° C. stirred. 0.299 g (0.8 mmol, 1 eq) Pt(COD)Cl₂ are added at room temperature and the reaction mixture is stirred at room temperature for 3 h and then at 125° C. for 21 h. After cooling to room temperature, 0.538 g (1.6 mmol, 2 eq) bis-I, 3-(2,3,5,6-tetramethylphenyl) propane-I, 3-dione and 0.180 g (1.6 mmol, 2 eq) of potassium tert-butoxide are added and the mixture is first stirred at room temperature for 21 h, then at 100° C. for 6 h. After removing the solvents in vacuo, the residue is washed with water, filtered and the filter cake is dried at 60° C. overnight. The solid is extracted with DCM and then eluted by means of column chromatography separation with a gradient of iso-hexane/DCM in a ratio of 1:2. The solid obtained is then washed with iso-hexane in an ultrasonic bath (3×5 ml each). After drying in vacuo, the product is obtained as a yellow solid (55 mg, 8%).

Melting point: >300° C. (decomposition)

¹H NMR (600 MHz, CDCl₃)

δ=7.81 (dd, J=7.6, 1.5 Hz, 1H), 7.58-7.51 (m, 1H), 7.51-7.44 (m, 2H), 7.37-7.33 (m, 2H), 7.33-7.27 (m, 3H), 7.17-7.11 (m, 2H), 7.11 (s, 1H), 6.93 (s, 1H), 6.90-6.84 (m, 2H), 6.65 (ddd, J=8.2, 7.3, 1.5 Hz, 1H), 6.29 (dd, J=8.1, 1.2 Hz, 1H), 5.57 (s, 1H), 2.29 (s, 6H), 2.26 (s, 6H), 2.23 (s, 6H), 2.19 (s, 6H).

¹³C NMR (151 MHz, CDCl₃)

δ=185.7 (CO), 185.3 (CO), 147.9 (Cᵢ), 143.3 (Cᵢ), 143.2 (Cᵢ), 139.2 (Cᵢ), 136.1 (Cᵢ), 133.8 (CHₐᵣₒₘ), 133.6 (Cᵢ), 131.9 (Cᵢ), 131.5 (CHₐᵣₒₘ), 130.9 (CHₐᵣₒₘ), 130.9 (CHₐᵣₒₘ), 130.8 (CHₐᵣₒₘ), 129.9 (Cᵢ), 129.7 (Cᵢ), 129.5 (CHₐᵣₒₘ), 129.5 (CHₐᵣₒₘ), 129.2 (CHₐᵣₒₘ), 125.9 (CHₐᵣₒₘ), 125.8 (CHₐᵣₒₘ), 124.6 (Cᵢ), 122.7 (CHₐᵣₒₘ), 121.4 (CHₐᵣₒₘ), 113.5 (CHₐᵣₒₘ), 107.5 (CHₐᵣₒₘ), 19.9 (CCH₃), 19.8 (CCH₃), 16.6 (CCH₃), 16.5 (CCH₃).

Two missing Cᵢ resonances are not resolved in the spectrum.

¹⁹⁵Pt NMR (64 MHz, CDCl₃) δ=−3318.1 (s).

Elemental analysis calculated for C₄₄H₄₂N₂O₂Pt: C, 63.99; H, 5.13; N, 3.39; Found: C, 64.11; H, 5.36; N, 3.32.

### Complex E

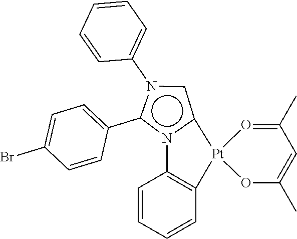

In a Schlenk tube, 0.370 g (0.8 mmol) of 2-(4-bromophenyl)-1,3-diphenyl-1H-imidazolium tetrafluoroborate and 0.093 g (0.4 mmol, 0.5 eq) of silver (I) oxide are suspended in 20 ml of dry DMF and stirred at 75° C. for 24. 0.299 g (0.8 mmol, 1 eq) Pt(COD)Cl₂ are added at room temperature and the reaction mixture is first stirred at room temperature for 3 h and then at 125° C. for 21 h. After cooling to room temperature, 0.160 g (1.6 mmol, 2 eq) acetylacetone and 0.221 g (1.6 mmol, 2 eq) potassium carbonate are added, and the mixture is stirred at room temperature for 21 h, then at 100° C. for 6 h. After removing the solvents in vacuo, the residue is washed with water, filtered and the filter cake is dried at 60° C. overnight. The solid is extracted with DCM and then purified by means of column chromatography with the eluent DCM. The solid obtained is then washed with iso-hexane in an ultrasonic bath (3×5 ml each). After drying in vacuo, the product is obtained as a brown solid (135 mg, 25%).

Melting point: >250° C. (dec.)

¹H NMR (600 MHz, CDCl₃)

δ=7.96-7.80 (m, 1H, CHₐᵣₒₘ), 7.61 (d, J=8.4 Hz, 2H, CHₐᵣₒₘ), 7.37 (m, 3H, CHₐᵣₒₘ), 7.25 (d, J=9.8 Hz, 2H, CHₐᵣₒₘ), 7.16 (d, J=6.9 Hz, 2H, CHₐᵣₒₘ), 7.11 (s, 1H, CHₐᵣₒₘ), 6.98 (t, J=7.4 Hz, 1H, CHₐᵣₒₘ), 6.72 (t, J=7.7 Hz, 1H, CHₐᵣₒₘ), 6.34 (d, J=8.0 Hz, 1H, CHₐᵣₒₘ), 5.44 (s, 1H, COCH), 2.02 (s, 3H, CCH₃), 1.93 (s, 3H, CCH₃).

¹³C NMR (151 MHz, CDCl₃)

δ=185.0 (CO), 184.9 (CO), 147.7 (Cᵢ), 138.1 (Cᵢ), 136.0 (Cᵢ), 133.3 (CHₐᵣₒₘ), 133.0 (Cᵢ), 132.9 (CHₐᵣₒₘ), 132.5 (CHₐᵣₒₘ), 130.3 (Cᵢ), 129.8 (CHₐᵣₒₘ), 129.5 (CHₐᵣₒₘ), 126.4 (Cᵢ), 126.1 (CHₐᵣₒₘ), 126.0 (CHₐᵣₒₘ), 123.4 (Cᵢ), 122.6 (CHₐᵣₒₘ), 121.3 (CHₐᵣₒₘ), 113.5 (CHₐᵣₒₘ), 102.0 (CHₐᵣₒₘ), 28.2 (CCH₃), 28.0 (CCH₃).

¹⁹⁵Pt NMR (64 MHz, CDCl₃)

δ=−3374.5 (s).

Elemental analysis calculated for C₂₆H₂₁BrN₂O₂Pt: C, 46.72; H, 3.17; N, 4.19; Found: C, 46.84; H, 3.26; N, 4.39.

### Complex F

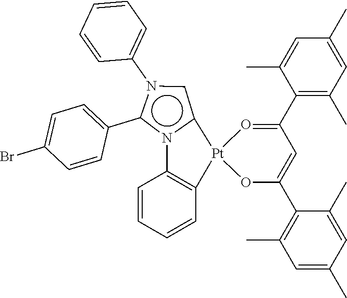

In a Schlenk tube, 0.556 g (1.2 mmol) of 2-(4-bromophenyl)-1,3-diphenyl-1H-imidazolium tetrafluoroborate and 0.139 g (0.6 mmol, 0.5 eq) of silver (I) oxide are suspended in 30 ml of dry DMF and stirred at 75° C. for 24. 0.449 g (1.2 mmol, 1 eq) Pt(COD)Cl₂ are added at room temperature and the reaction mixture is first stirred at room temperature for 3 h and then at 125° C. for 21 h. After cooling to room temperature again 0.740 g (2.4 mmol, 2 eq) bis-1,3-(2,4,6-trimethylphenyl)propan-1,3-dione and 0.269 g (2.4 mmol, 2 eq) potassium tert-butanolate was added and the mixture was first stirred at room temperature for 21 h, then at 100° C. for 6 h. After removing the solvents in vacuo, the residue is washed with water, filtered and the filter cake is dried at 60° C. overnight. The solid is extracted with DCM and then eluted by column chromatography with a gradient of iso-hexane/DCM (2:5). The solid obtained is then washed with iso-hexane in an ultrasonic bath (3×5 ml each). After drying in vacuo, the product is obtained as a yellow solid (96 mg, 14%).

Melting point: >300° C. (decomposition)

¹H NMR (300 MHz, CDCl₃)

δ=7.96-7.68 (m, 1H, CHₐᵣₒₘ), 7.66-7.57 (m, 2H, CHₐᵣₒₘ), 7.42-7.27 (m, 3H, CHₐᵣₒₘ), 7.27-7.17 (m, 2H, CHₐᵣₒₘ), 7.14-7.09 (m, 2H, CHₐᵣₒₘ), 7.08 (s, 1H, CHₐᵣₒₘ), 6.91 (td, J=7.4, 1.2 Hz, 1H, CHₐᵣₒₘ), 6.85 (s, 2H, CHₐᵣₒₘ), 6.81 (s, 2H, CHₐᵣₒₘ), 6.70 (m, 1H, CHₐᵣₒₘ), 6.33 (dd, J=8.1, 1.1 Hz, 1H, CHₐᵣₒₘ), 5.61 (s, 1H, COCH), 2.39 (s, 6H, CCH₃), 2.35 (s, 6H, CCH₃), 2.30 (s, 3H, CCH₃), 2.26 (s, 3H, CCH₃).

¹³C NMR (75 MHz, CDCl₃)

δ=184.6 (CO), 184.2 (CO), 147.7 (Cᵢ), 140.2 (Cᵢ), 140.1 (Cᵢ), 138.0 (Cᵢ), 137.3 (Cᵢ), 137.3 (Cᵢ), 135.9 (Cᵢ), 134.3 (Cᵢ), 134.0 (Cᵢ), 133.9 (CHₐᵣₒₘ), 133.0 (CHₐᵣₒₘ), 132.6 (Cᵢ), 132.4 (CHₐᵣₒₘ), 129.9 (Cᵢ), 129.7 (CHₐᵣₒₘ), 129.5 (CHₐᵣₒₘ), 128.2 (CHₐᵣₒₘ), 128.1 (CHₐᵣₒₘ), 126.4 (Cᵢ), 126.0 (CHₐᵣₒₘ), 125.9 (CHₐᵣₒₘ), 123.4 (Cᵢ), 122.8 (CHₐᵣₒₘ), 121.6 (CHₐᵣₒₘ), 113.5 (CHₐᵣₒₘ), 107.0 (CHₐᵣₒₘ), 21.2 (CCH₃), 21.2 (CCH₃), 20.0 (CCH₃), 19.9 (CCH₃).

¹⁹⁵Pt NMR (64 MHz, CDCl₃)

δ=−3309.1 (s).

Elemental analysis calculated for C₄₂H₃₇BrN₂O₂Pt: C, 57.54; H, 4.25; N, 3.20; found: C, 57.63; H, 4.41; N, 3.18.

### Complex G

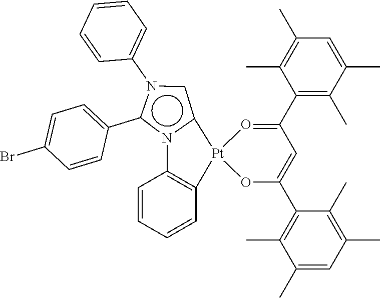

In a Schlenk tube, 0.556 g (1.2 mmol) of 2-(4-bromophenyl)-1,3-diphenyl-1H-imidazolium tetrafluoroborate and 0.139 g (0.6 mmol, 0.5 eq) of silver (I) oxide are suspended in 30 ml of dry DMF stirred at 75° C. for 24. 0.449 g (1.2 mmol, 1 eq) Pt(COD)Cl₂ are added at room temperature and the reaction mixture is first stirred at room temperature for 3 h and then at 125° C. for 21 h. After cooling to room temperature, 0.808 g (2.4 mmol, 2 eq) bis-1,3-(2,3,5,6-tetramethylphenyl)propane-1,3-dione and 0.269 g (2.4 mmol, 2 eq) of potassium tert-butanolate are added and the mixture is stirred at room temperature for 21 h, then at 100° C. for 6 h. After removing the solvents in vacuo, the residue is washed with water, filtered and the filter cake is dried at 60° C. overnight. The solid is extracted with DCM and then eluted by column chromatography with a gradient of iso-hexane/DCM (2:5). The solid obtained is then washed with iso-hexane in an ultrasonic bath (3×5 ml each).

After drying in vacuo, the product is obtained as a yellow solid (56 mg, 8%).

Melting point: >300° C. (decomposition)

¹H NMR (300 MHz, CDCl₃)

δ=7.95-7.71 (m, 1H, CHₐᵣₒₘ), 7.62 (d, J=8.4 Hz, 2H, CHₐᵣₒₘ), 7.40-7.28 (m, 3H, CHₐᵣₒₘ), 7.22 (d, J=8.4 Hz, 2H, CHₐᵣₒₘ), 7.16-7.07 (m, 3H, CHₐᵣₒₘ), 6.98-6.86 (m, 3H, CHₐᵣₒₘ), 6.75-6.64 (m, 1H, CHₐᵣₒₘ), 6.33 (dd, J=8.1, 1.2 Hz, 1H, CHₐᵣₒₘ), 5.57 (s, 1H, COCH), 2.29 (s, 6H, CCH₃), 2.25 (s, 6H, CCH₃), 2.23 (s, 6H, CCH₃), 2.19 (s, 6H, CCH₃).

¹³C NMR (75 MHz, CDCl₃) δ 185.8 (CO), 185.3 (CO), 147.73, 143.28, 143.23, 135.92, 134.00, 133.68, 133.01, 132.66, 132.46, 130.97, 130.89, 129.93, 129.77, 129.71, 129.48, 126.44, 126.03, 125.92, 123.47, 122.79, 121.79, 113.47, 107.56, 19.91, 19.84, 16.66, 16.58.

¹⁹⁵Pt NMR (64 MHz, CDCl₃)

δ=−3320.8 (s).

Elemental analysis calculated for C₄₄H₄₁BrN₂O₂Pt: C, 58.41; H, 4.57; N, 3.10; found: C, 58.25; H, 4.97; N, 3.06.

### Complex H

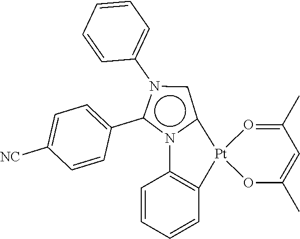

In a Schlenk tube, 0.327 g (0.8 mmol) of 2-(4-cyanophenyl)-1, 3-diphenyl-1H-imidazolium tetrafluoroborate and 0.093 g (0.64 mmol, 0.8 eq) of silver (I) oxide are suspended in 20 ml of dry DMF stirred at 75° C. for 24. 0.299 g (0.8 mmol, 1 eq) Pt(COD)Cl₂ are added at room temperature and the reaction mixture is first stirred at room temperature for 3 h and then at 125° C. for 21 h. After cooling to room temperature, 0.320 g (3.2 mmol, 4 eq) of acetylacetone and 0.442 g (3.2 mmol, 4 eq) of potassium carbonate are again added and the mixture is stirred at room temperature for 21 h and then at 100° C. for 6 h. After removing the solvents in vacuo, the residue is washed with water, filtered and the filter cake is dried at 60° C. overnight. The solid is extracted with DCM and then purified by means of column chromatography with the eluent mixture DCM/MeOH (1% MeOH). The solid obtained is then washed with iso-hexane in an ultrasonic bath (3×5 ml each). After drying in vacuo, the product is obtained as a brown solid (130 mg, 26%).

Melting point: >250° C. (dec.)

¹H NMR (600 MHz, CDCl₃)

δ=7.89 (dd, J=7.6, 1.4 Hz, 1H, CHₐᵣₒₘ), 7.76 (d, J=8.1 Hz, 2H, CHₐᵣₒₘ), 7.53 (d, J=8.2 Hz, 2H, CHₐᵣₒₘ), 7.44-7.34 (m, 3H), 7.18-7.12 (m, 3H, CHₐᵣₒₘ), 7.00 (td, J=7.4, 1.2 Hz, 1H, CHₐᵣₒₘ), 6.75-6.67 (m, 1H, CHₐᵣₒₘ), 6.27 (dd, J=8.1, 1.1 Hz, 1H, CHₐᵣₒₘ), 5.45 (s, 1H, COCH), 2.03 (s, 3H, CCH₃), 1.94 (s, 3H, CCH₃).

¹³C NMR (151 MHz, CDCl₃)

δ=185.1 (CO), 184.9 (CO), 147.4 (Cᵢ), 136.9 (Cᵢ), 135.6 (Cᵢ), 134.0 (Cᵢ), 133.5 (CHₐᵣₒₘ), 133.1 (CHₐᵣₒₘ), 131.9 (CHₐᵣₒₘ), 130.5 (Cᵢ), 130.0 (CHₐᵣₒₘ), 129.9 (CHₐᵣₒₘ), 129.0 (Cᵢ), 126.3 (CHₐᵣₒₘ), 126.0 (CHₐᵣₒₘ), 122.6 (CHₐᵣₒₘ), 121.8 (CHₐᵣₒₘ), 117.5 (Cᵢ), 115.5 (Cᵢ), 113.4 (CHₐᵣₒₘ), 102.1 (CHₐᵣₒₘ), 28.2 (CCH₃), 28.0 (CCH₃).

¹⁹⁵Pt NMR (64 MHz, CDCl₃)

δ=−3374.6 (s).

Elemental analysis calculated for C₂₇H₂₁N₃O₂Pt: C, 52.77; H, 3.44; N, 6.84; found: C, 52.45; H, 3.27; N, 6.86.

### Complex I

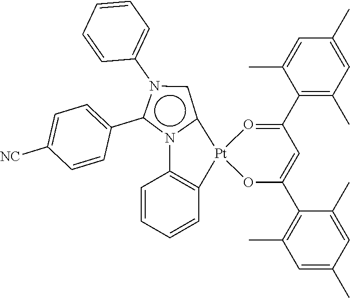

In a Schlenk tube, 0.491 g (1.2 mmol) of 2-(4-cyanophenyl)-1, 3-diphenyl-1H-imidazolium tetrafluoroborate and 0.139 g (0.6 mmol, 0.5 eq) of silver (I) oxide are suspended in 30 ml of dry DMF stirred at 75° C. for 24. 0.449 g (1.2 mmol, 1 eq) Pt(COD)Cl₂ are added at room temperature and the reaction mixture is first stirred at room temperature for 3 h and then at 125° C. for 21 h. After cooling to room temperature again 0.740 g (2.4 mmol, 2 eq) bis-I, 3-(2,4,6-trimethylphenyl) propane-I, 3-dione and 0.269 g (2.4 mmol, 2 eq) Potassium tert-butanolate was added and the mixture was stirred at room temperature for 21 h, then at 100° C. for 6 h. After removing the solvents in vacuo, the residue is washed with water, filtered and the filter cake is dried at 60° C. overnight. The solid is extracted with DCM and then eluted by column chromatography with a gradient of iso-hexane/DCM (2:5). The solid obtained is then washed with iso-hexane in an ultrasonic bath (3×5 ml each). After drying in vacuo, the product is obtained as a yellow solid (134 mg, 20%).

Melting point: >300° C. (decomposition)

¹H NMR (300 MHz, CDCl₃)

δ=7.99-7.68 (m, 3H, CHₐᵣₒₘ), 7.50 (d, J=8.4 Hz, 2H, CHₐᵣₒₘ), 7.42-7.29 (m, 3H, CHₐᵣₒₘ), 7.19-7.04 (m, 3H, CHₐᵣₒₘ), 6.92 (td, J=7.4, 1.2 Hz, 1H, CHₐᵣₒₘ), 6.83 (d, J=14.4 Hz, 4H, CHₐᵣₒₘ), 6.69 (td, J=7.8, 7.4, 1.5 Hz, 1H, CHₐᵣₒₘ), 6.26 (dd, J=8.1, 1.1 Hz, 1H, CHₐᵣₒₘ), 5.62 (s, 1H, COCH), 2.38 (s, 6H, CCH₃), 2.34 (s, 6H, CCH₃), 2.29 (s, 3H, CCH₃), 2.25 (s, 3H, CCH₃).

¹³C NMR (75 MHz, CDCl₃)

δ=184.7 (CO), 184.3 (CO), 147.4 (Cᵢ), 140.1 (Cᵢ), 140.0 (Cᵢ), 137.4 (2 Cᵢ), 136.8 (Cᵢ), 135.5 (Cᵢ), 134.2 (Cᵢ), 134.0 (CHₐᵣₒₘ), 133.6 (Cᵢ), 133.1 (CHₐᵣₒₘ), 131.9 (CHₐᵣₒₘ), 130.2 (Cᵢ), 129.9 (CHₐᵣₒₘ), 129.8 (CHₐᵣₒₘ), 129.0 (Cᵢ), 128.2 (CHₐᵣₒₘ), 128.1 (CHₐᵣₒₘ), 126.3 (CHₐᵣₒₘ), 125.9 (CHₐᵣₒₘ), 122.8 (CHₐᵣₒₘ), 122.2 (CHₐᵣₒₘ), 117.4 (Cᵢ), 115.5 (Cᵢ), 113.3 (CHₐᵣₒₘ), 107.1 (CHₐᵣₒₘ), 100.1 (Cᵢ), 21.2 (2 CCH₃), 20.0 (CCH₃), 19.9 (CCH₃).

¹⁹⁵Pt NMR (64 MHz, CDCl₃)

δ=−3314.12 (d, J=55.4 Hz).

Elemental analysis calculated for C₄₃H₃₇N₃O₂Pt: C, 62.76; H, 4.53; N, 5.11; found: C, 63.00; H, 4.59; N, 5.03.

### Complex J

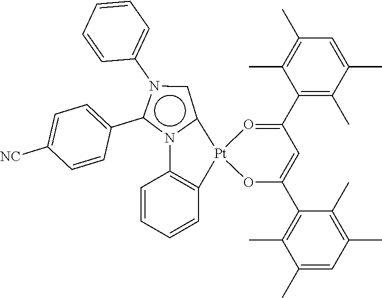

In a Schlenk tube, 0.491 g (1.2 mmol) of 2-(4-cyanophenyl)-1,3-diphenyl-1H-imidazolium tetrafluoroborate and 0.139 g (0.6 mmol, 0.5 eq) of silver (I) oxide are suspended in 30 ml of dry DMF and stirred at 75° C. for 24. 0.449 g (1.2 mmol, 1 eq) Pt(COD)Cl₂ are added at room temperature and the reaction mixture is first stirred at room temperature for 3 h and then at 125° C. for 21 h. After cooling to room temperature, 0.808 g (2.4 mmol, 2 eq) of bis-1,3, (2,3,5,6-tetramethylphenyl) propane-1,3-dione and 0.269 g (2.4 mmol, 2 eq) of potassium tert-butanolate are added and the mixture is first stirred at room temperature for 21 h, then at 100° C. for 6 h. After removing the solvents in vacuo, the residue is washed with water, filtered and the filter cake is dried at 60° C. overnight. The solid is extracted with DCM and then eluted by column chromatography with a gradient of iso-hexane/DCM (2:5). The solid obtained is then washed with iso-hexane in an ultrasonic bath (3×5 ml each). After drying in vacuo, the product is obtained as a yellow solid (32 mg, 5%).

Melting point: >300° C. (decomposition)

¹H NMR (300 MHz, CDCl₃)

δ=7.98-7.66 (m, 3H, CHₐᵣₒₘ), 7.50 (d, J=8.4 Hz, 2H, CHₐᵣₒₘ), 7.42-7.29 (m, 3H, CHₐᵣₒₘ), 7.15 (s, 1H, CHₐᵣₒₘ), 7.09 (dd, J=8.0, 1.7 Hz, 2H, CHₐᵣₒₘ), 6.97-6.84 (m, 3H, CHₐᵣₒₘ), 6.69 (td, J=7.7, 1.5 Hz, 1H, CHₐᵣₒₘ), 6.26 (dd, J=8.0, 1.1 Hz, 1H, CHₐᵣₒₘ), 5.58 (s, 1H, COCH), 2.28 (s, 6H, CCH₃), 2.25 (s, 6H, CCH₃), 2.23 (s, 6H, CCH₃), 2.19 (s, 6H, CCH₃).

¹⁹⁵Pt NMR (64 MHz, CDCl₃)

δ=−3325.0 (s).

Elemental analysis calculated for C₄₅H₄₁N₃O₂Pt: C, 62.76; H, 4.53; N, 5.11; found: C, 63.05; H, 4.40; N, 4.71.

### Structure and Photophysical Characterization

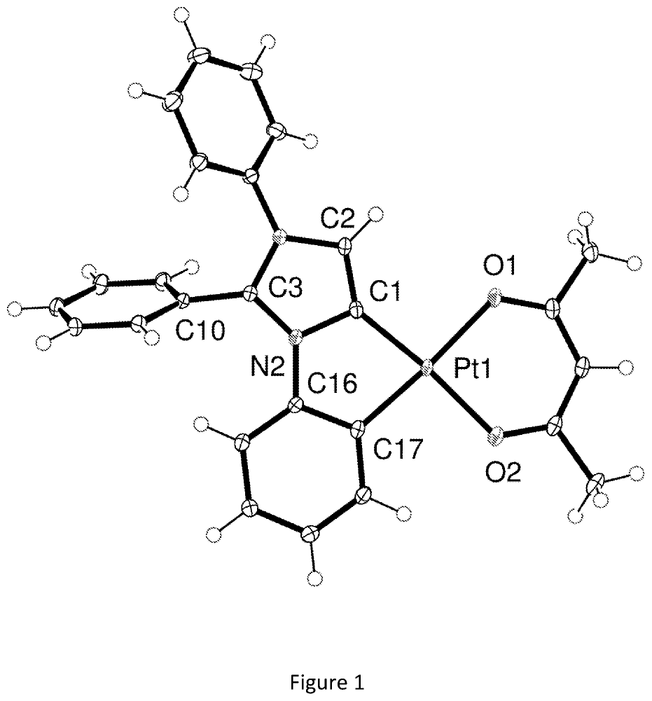

The crystal structure of compound B is shown in FIG. 1. The bond between the carbene carbon atom of the imidazole ring (denoted by “C1” in FIG. 1) and the platinum atom (denoted by “Pt1” in FIG. 1) is clearly recognizable therein.

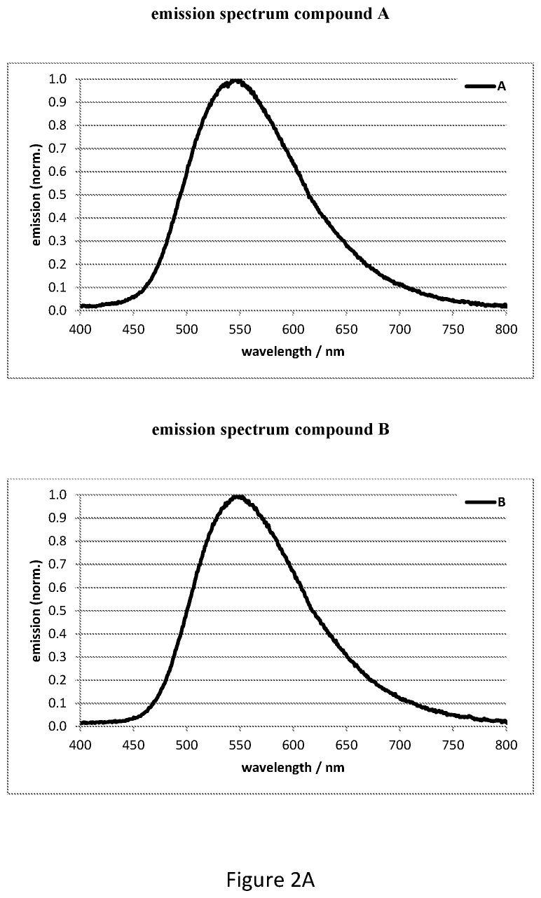

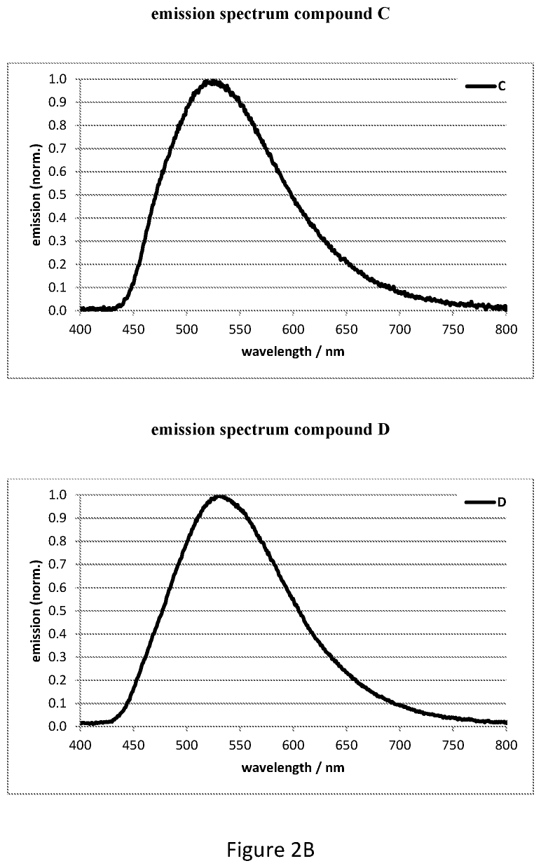

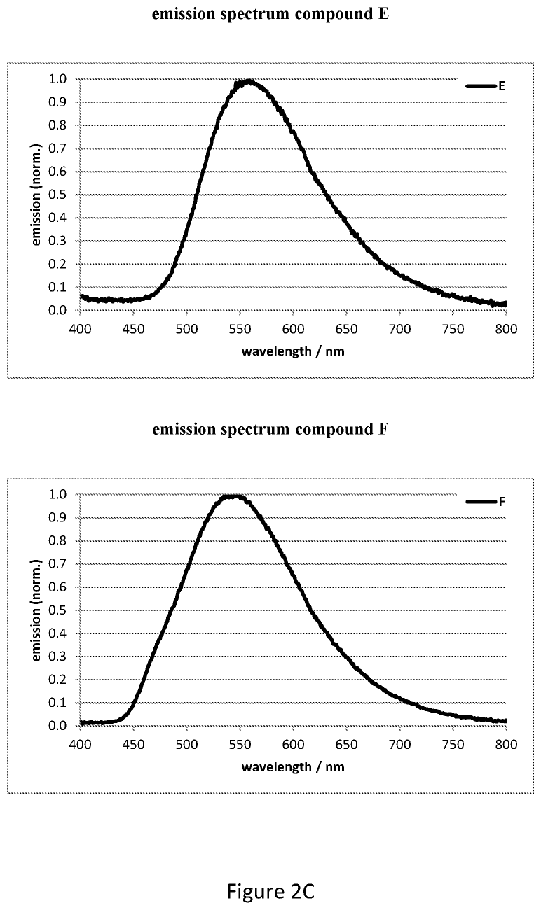

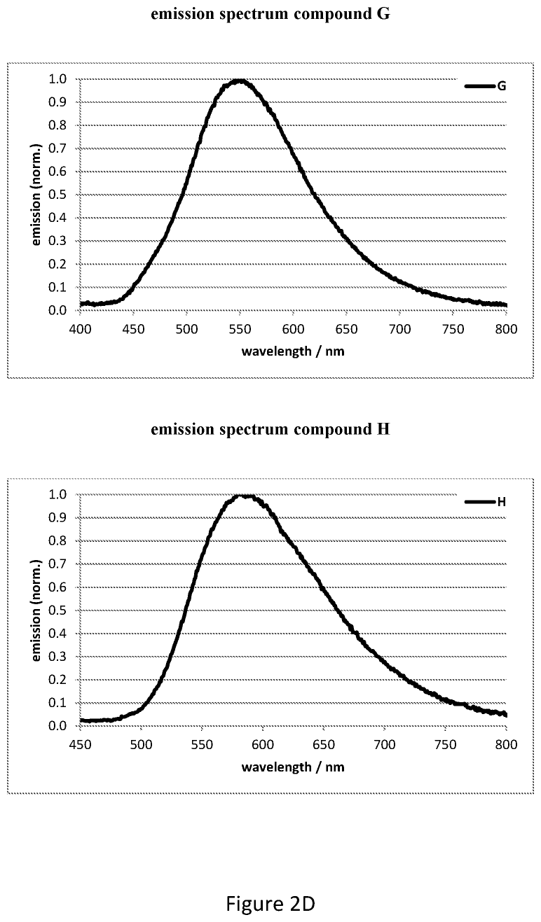

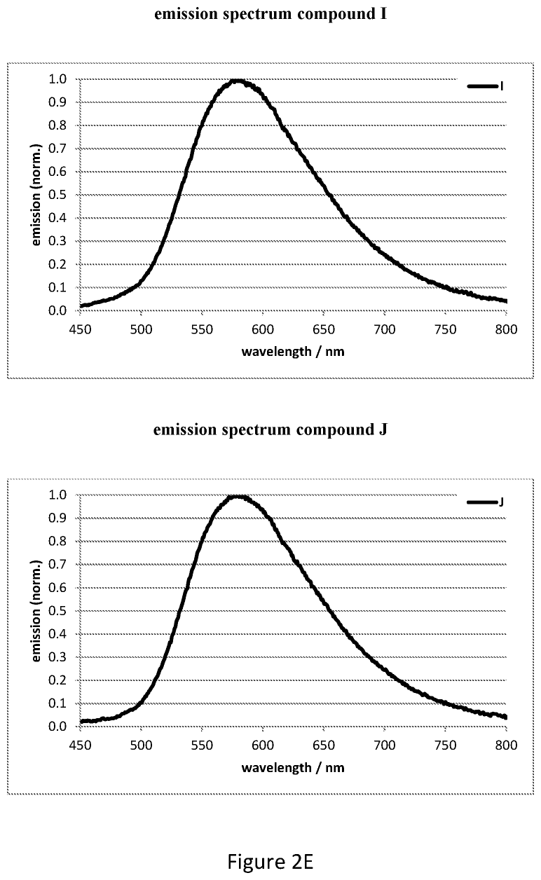

The absorption spectra for the compounds A to J are shown in FIGS. 2A to 2E. The spectra were measured in an air atmosphere in dichloromethane at a concentration of 5·10⁻⁵ mol/l.

The spectra show an emission of the respective compound in the visible range and prove suitability for use in OLEDs.

TABLE 1
Photoluminescence data of complexes A to J, measured
at room temperature in PMMA films each containing
2% by weight of the respective complex

| | λ_{exc} | CIE | λₑₘ | Φ | τ₀ |
|---|---|---|---|---|---|
| complex | [nm] | x; y | [nm] | [%] | [μs] |
| A | 290 | 0.384; 0.528 | 544 | 60 | 45 |
| B | 290 | 0.401; 0.534 | 548 | 70 | 32 |
| C | 370 | 0.326; 0.496 | 523 | 67 | 19 |
| D | 290 | 0.340; 0.496 | 531 | 72 | 27 |
| E | 290 | 0.432; 0.527 | 558 | 45 | 46 |
| F | 290 | 0.371; 0.507 | 547 | 71 | 26 |
| G | 290 | 0.386; 0.511 | 551 | 57 | 35 |
| H | 290 | 0.508; 0.480 | 579 | 56 | 35 |
| I | 290 | 0.489; 0.489 | 578 | 63 | 28 |
| J | 290 | 0.493; 0.489 | 579 | 64 | 29 |

λ_{exc} = excitation wavelength; CIE = CIE coordinates at room temperature, λₑₘ maximum emission wavelength at room temperature, Φ = quantum yield at λ_{exc}, τ₀ = phosphorescence lifetime given as als τ₀ = τᵥ/Φ, wherein τᵥ = measured phosphorescence lifetime.

The compounds exhibit significant luminescence in the green to yellow region of the visible spectrum with emission wavelength λₑₘ of the highest intensity at room temperature λₑₘ=523 nm (complex C) and 579 nm (complexes H, J).

Further photophysical characteristics of compounds A to J can be found in Table 1.

1. A platinum (II) complex of the following formula (I): 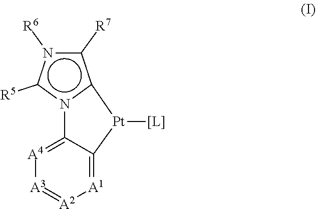
wherein
A¹ is Nor CR¹,
A² is N or CR²,
A³ is N or CR³,
A⁴ is N or CR⁴,
wherein R¹ to R⁴ are each independently selected from H, a linear or branched, substituted or unsubstituted alkyl residue having 1 to 20 carbon atoms, wherein at least one carbon atom is optionally replaced by a heteroatom, a substituted or unsubstituted cycloalkyl residue having 3 to 20 carbon atoms, wherein at least one carbon atom is optionally replaced by a heteroatom, a substituted or unsubstituted aryl residue having 6 to 30 carbon atoms, a substituted or unsubstituted heteroaryl residue having 5 to 18 carbon and/or heteroatoms, or a group with acceptor or donor properties,
or R¹ and R², R² and R³, and/or R³ and R⁴ together with the atoms to which they are attached form a condensed aromatic ring system having 5 to 18 carbon and/or heteroatoms, the condensed aromatic ring system being substituted or unsubstituted,
R⁵ and R⁶ are each independently selected from a linear or branched, substituted or unsubstituted alkyl residue having 1 to 20 carbon atoms wherein at least one carbon atom is optionally replaced by a hetero atom, a substituted or unsubstituted cycloalkyl residue having 3 to 20 carbon atoms, wherein at least one carbon atom is optionally replaced by a hetero atom, a substituted or unsubstituted aryl residue having 6 to 30 carbon atoms, a substituted or unsubstituted heteroaryl residue having 5 to 18 carbon and/or heteroatoms, or a group with acceptor or donor properties,
R⁷ is selected from H, a linear or branched, substituted or unsubstituted alkyl residue having 1 to 20 carbon atoms, wherein at least one carbon atom is replaced by a hetero atom, a substituted or unsubstituted cycloalkyl residue having 3 to 20 carbon atoms, wherein at least one carbon atom is optionally replaced by a hetero atom, a substituted or unsubstituted aryl residue having 6 to 30 Carbon atoms, a substituted or unsubstituted heteroaryl residue having 5 to 18 carbon and/or heteroatoms, or a group with acceptor or donor properties, or
R⁵ and R⁶ or R⁶ and R⁷ together with the atoms to which they are attached form a condensed aromatic ring system having 5 to 18 carbon and/or heteroatoms, the condensed aromatic ring system being substituted or unsubstituted,
or R⁴ and R⁵ together with the atoms to which they are attached form a condensed aromatic ring system having 6 to 18 carbon and/or heteroatoms, the condensed aromatic ring system being substituted or unsubstituted,
L is a bidentate monoanionic ligand, and
wherein R¹ to R⁷ and L each optionally carry one or more functional groups having donor or acceptor properties.

2. The platinum (II) complex according to claim 1, wherein L is a bidentate monoanionic ligand of the formula (II): 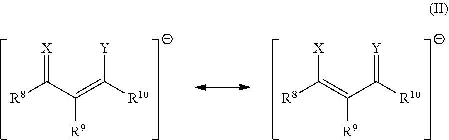
wherein
X and Y are selected independently of one another from O, S or NR¹¹,
R⁸ and R¹⁰ are selected independently of one another from a linear or branched, substituted or unsubstituted alkyl residue having 1 to 20 carbon atoms, wherein at least one carbon atom is optionally replaced by a heteroatom, a substituted or unsubstituted cycloalkyl residue having 3 to 20 carbon atoms, wherein at least one carbon atom is optionally replaced by a hetero atom, a substituted or unsubstituted aryl residue having 6 to 30 carbon atoms, a substituted or unsubstituted heteroaryl residues having 5 to 18 carbon and/or heteroatoms,
R⁹ and R¹¹ are selected independently of one another from H, a linear or branched, substituted or unsubstituted alkyl residue having 1 to 20 carbon atoms, wherein at least one carbon atom is optionally replaced by a hetero atom, a substituted or unsubstituted cycloalkyl residue having 3 to 20 carbon atoms, wherein at least one carbon atom is optionally replaced by a hetero atom, a substituted or unsubstituted aryl residue having 6 to 30 carbon atoms, a substituted or unsubstituted heteroaryl residue having 5 to 18 carbon and/or heteroatoms, or
R³ and R⁹, R⁹ and R¹⁰, R³ and R¹¹ and/or R¹⁰ and R¹¹ together with the atoms to which they are attached form a condensed aromatic ring system having 5 to 18 carbon and/or heteroatoms, wherein the condensed aromatic ring system is substituted or unsubstituted, and
wherein R⁸ to R¹¹ and each optionally carry one or more functional groups having donor or acceptor properties, and wherein, when both X and Y are Y—NR¹¹, the respective residues R¹¹ are the same or different.

3. The platinum (II) complex according to claim 2, wherein X and Y are respectively the same.

4. The platinum (II) complex according to claim 1, wherein A¹ to A⁴ is CR¹ to CR⁴, and wherein at least two of R¹ to R⁴ together with the atoms, to which they are attached, form a condensed aromatic ring system.

5. The platinum (II) complex according to claim 1, wherein R⁷ is H.

6. The platinum (II) complex according to claim 5, wherein:
A¹ to A⁴ are respectively CR¹ to CR⁴,
R¹, R², R³, R⁴, and R⁹ are respectively H,
R⁵ is selected from the group consisting of phenyl, 4-bromophenyl, 4-cyanophenyl,
R⁶ is selected from the group consisting of methyl and phenyl,
R⁸, R¹¹ are each selected independently of one another from the group consisting of methyl, tert-butyl, mesityl, and duryl.

7. An OLED, containing at least one platinum (II) complex according to claim 1.

8-10. (canceled)

11. A method of using a platinum (II) complex according to claim 1, comprising using the platinum (II) in OLEDs.

12. The method according to claim 11, comprising using the platinum (II) complex as an emitter, matrix material, charge transport material and/or charge blocker.
